(19) United States
(12) Patent Application Publication
(10) Pub. No.: US 2025/0364341 A1
(43) Pub. Date: Nov. 27, 2025

(54) SEMICONDUCTOR DEVICE, SEMICONDUCTOR DEVICE ASSEMBLY, VEHICLE, AND METHOD FOR MANUFACTURING SEMICONDUCTOR DEVICE

(71) Applicant: Rohm Co., Ltd., Kyoto-shi (JP)

(72) Inventors: Daiki IKEDA, Kyoto-shi (JP); Kohei TANIKAWA, Kyoto-shi (JP); Tomohiro YASUNISHI, Kyoto-shi (JP); Soichiro TAKAHASHI, Kyoto-shi (JP)

(21) Appl. No.: 19/294,459

(22) Filed: Aug. 8, 2025

Related U.S. Application Data
(63) Continuation of application No. PCT/JP2024/002398, filed on Jan. 26, 2024.

(30) Foreign Application Priority Data
Feb. 16, 2023 (JP) 2023-022537

(51) Int. Cl. H01L 23/31; H01L 21/56; H01L 23/00; H01L 23/29; H01L 23/367; H01L 23/498; H01L 23/538; H01L 25/07; H10D 80/20

(52) U.S. Cl. CPC H01L 23/3121; H01L 21/56; H01L 23/293; H01L 23/49866; H01L 23/5383; H01L 23/3677; H01L 23/49838; H01L 24/32; H01L 24/40; H01L 24/48; H01L 24/73; H01L 25/072; H01L 2224/32225; H01L 2224/40137; H01L 2224/48225; H01L 2224/73221; H01L 2224/73263; H01L 2224/73265; H10D 80/251

(57) ABSTRACT

A semiconductor device includes a support substrate, a semiconductor element, and a sealing resin. The support substrate includes a support surface facing a first side in the thickness direction and a bottom surface facing a second side in the thickness direction. The semiconductor element is disposed on the support surface. The sealing resin covers the semiconductor element and a portion of the support substrate. The bottom surface is exposed from the sealing resin and includes a grinding trace. The sealing resin includes a resin obverse surface facing the first side in the thickness direction and a first resin reverse surface facing the second side in the thickness direction. The first resin reverse surface surrounds the bottom surface as viewed in the thickness direction and is located on the first side in the thickness direction relative to the bottom surface.

### TECHNICAL FIELD

The present disclosure relates to a semiconductor device, a semiconductor device assembly, a vehicle, and a method for manufacturing a semiconductor device.

### BACKGROUND ART

Various configurations have been proposed for a semiconductor device including a semiconductor element. An example of a conventional semiconductor device is disclosed in Patent JP-A-2021-190505. The semiconductor device disclosed in JP-A-2021-190505 includes a semiconductor element, a support substrate, and a sealing resin. The semiconductor element is supported on the support substrate. The support substrate includes an insulating substrate and metal layers deposited on opposite surfaces of the insulating substrate. The metal layers are made of Cu (copper), for example. The bottom surface of the metal layer on the reverse side of the support substrate is exposed from the sealing resin. A heat sink can be attached to the bottom surface of the reverse-side metal layer. The heat sink may be bonded to the reverse-side metal layer of the support substrate via a bonding layer, for example. To enhance the adhesion in bonding the heat sink, the bottom surface of the reverse-side metal layer may need to have an improved flatness.

### BRIEF DESCRIPTION OF THE DRAWINGS

FIG. 1 is a perspective view showing a semiconductor device according to a first embodiment of the present disclosure.

FIG. 2 is a perspective view corresponding to FIG. 1, with a sealing resin omitted.

FIG. 3 is a perspective view corresponding to FIG. 2, with a first conductive member omitted.

FIG. 4 is a plan view showing the semiconductor device according to the first embodiment of the present disclosure.

FIG. 5 is a plan view corresponding to FIG. 4, with the sealing resin 4 indicated by imaginary lines.

FIG. 6 is a partial enlarged view in which a portion of FIG. 5 is enlarged, with the sealing resin omitted.

FIG. 7 is a plan view corresponding to FIG. 5, with the sealing resin and the first conductive member omitted and the second conductive member indicated by imaginary lines.

FIG. 8 is a bottom view showing the semiconductor device according to the first embodiment of the present disclosure.

FIG. 9 is a sectional view taken along line IX-IX in FIG. 5.

FIG. 10 is a sectional view taken along line X-X in FIG. 5.

FIG. 11 is a partial enlarged view in which a portion of FIG. 10 is enlarged.

FIG. 12 is a partial enlarged view in which a portion of FIG. 10 is enlarged.

FIG. 13 is a sectional view taken along line XIII-XIII in FIG. 5.

FIG. 14 is a sectional view taken along line XIV-XIV in FIG. 5.

FIG. 15 is a sectional view taken along line XV-XV in FIG. 5.

FIG. 16 is a partial enlarged view in which a portion of FIG. 14 is enlarged.

FIG. 17 is a sectional view showing a step of a method for manufacturing the semiconductor device according to the first embodiment of the present disclosure.

FIG. 18 is a sectional view showing a step subsequent to FIG. 17.

FIG. 19 is a sectional view showing a step subsequent to FIG. 18.

FIG. 20 is a sectional view showing an example of a semiconductor device assembly that includes the semiconductor device according to the first embodiment of the present disclosure.

FIG. 21 is a schematic view of a vehicle in which the semiconductor device according to the first embodiment of the present disclosure is mounted.

FIG. 22 is a bottom view showing a semiconductor device according to a first variation of the first embodiment.

FIG. 23 is a sectional view showing the semiconductor device according to the first variation of the first embodiment.

FIG. 24 is a partial enlarged view in which a portion of FIG. 23 is enlarged.

FIG. 25 is a bottom view showing a semiconductor device according to a second variation of the first embodiment.

FIG. 26 is a sectional view showing the semiconductor device according to the second variation of the first embodiment.

FIG. 27 is a partial enlarged view in which a portion of FIG. 26 is enlarged.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

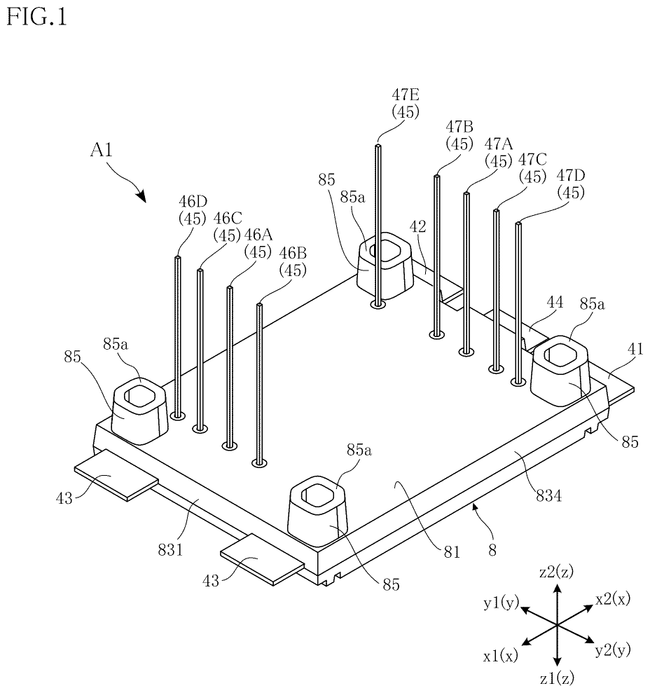

FIGS. 1 to 16 show a semiconductor device according to a first embodiment of the present disclosure. The semiconductor device A1 of the present embodiment includes a plurality of first semiconductor elements 10A, a plurality of second semiconductor elements 10B, a conductive substrate 2, a support substrate 3, a first terminal 41, a second terminal 42, a plurality of third terminals 43, a fourth terminal 44, a plurality of control terminals 45, a control terminal support 48, a first conductive member 5, a second conductive member 6, and a sealing resin 8.

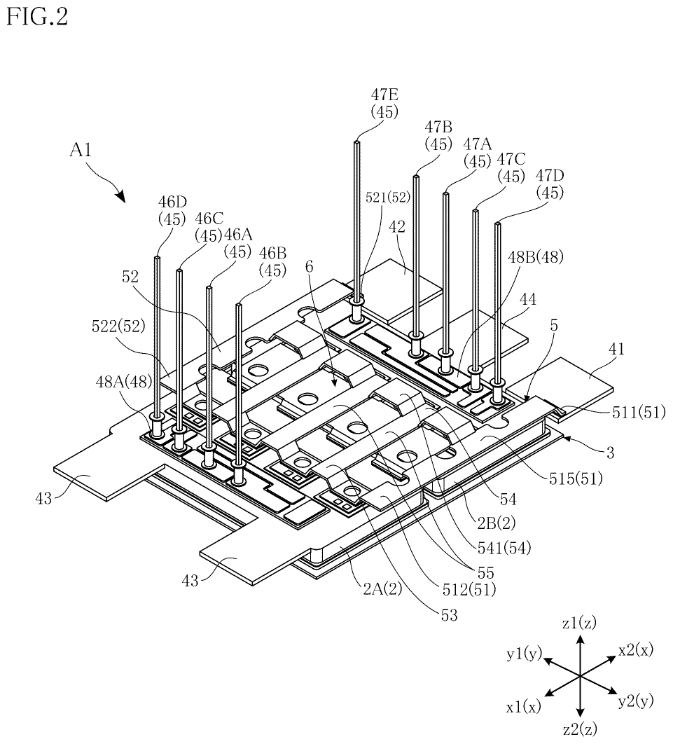

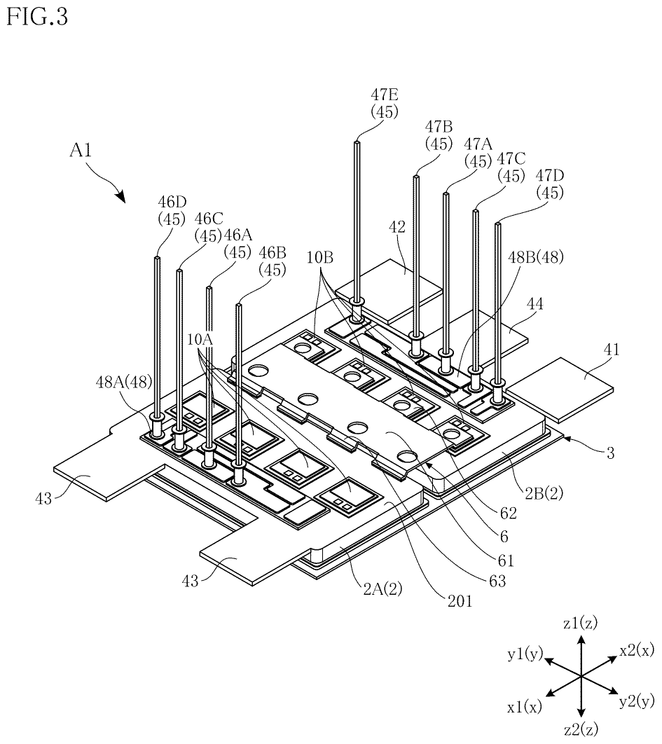

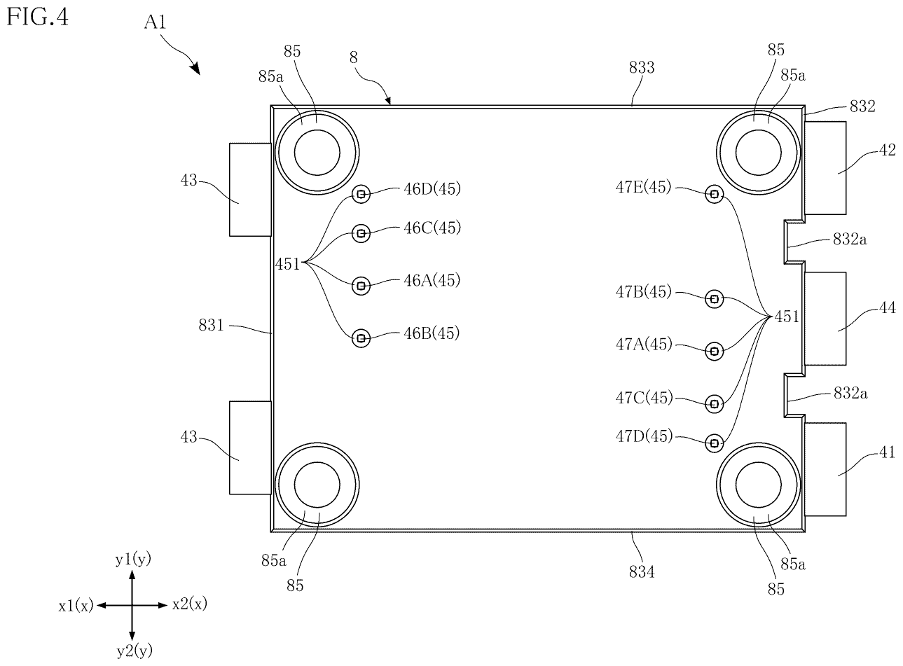

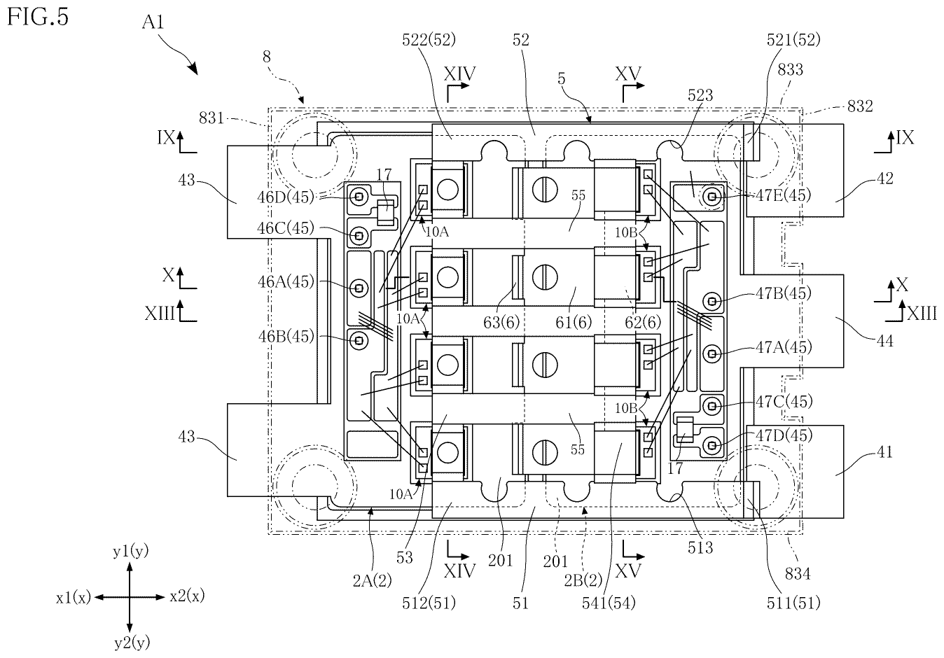

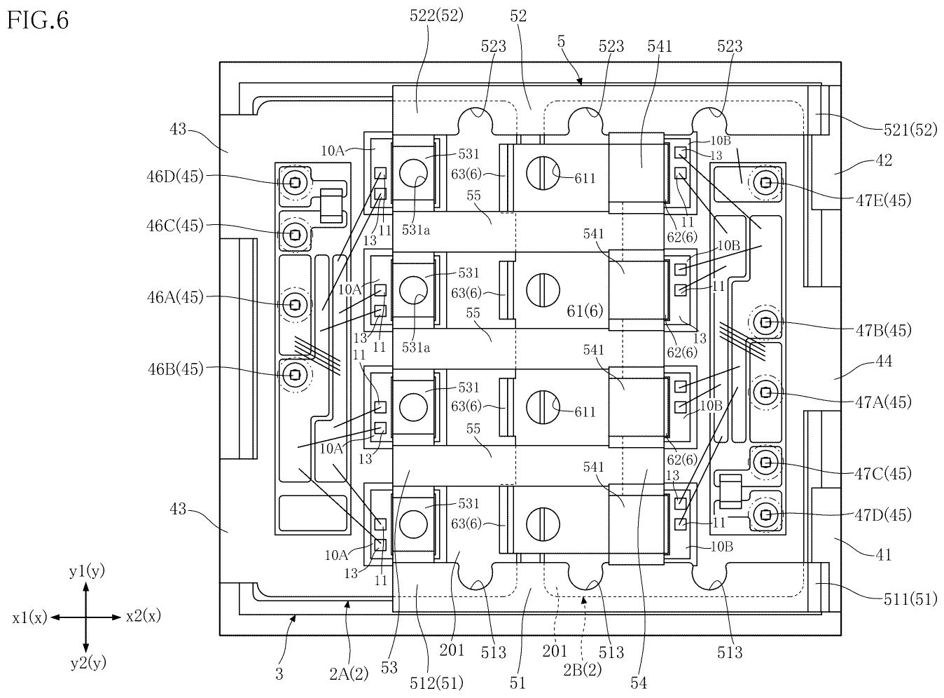

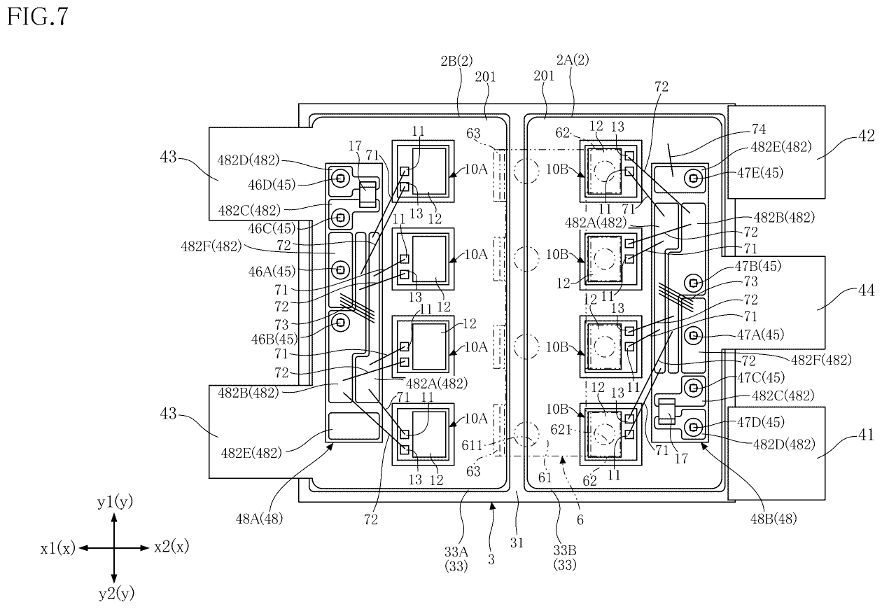

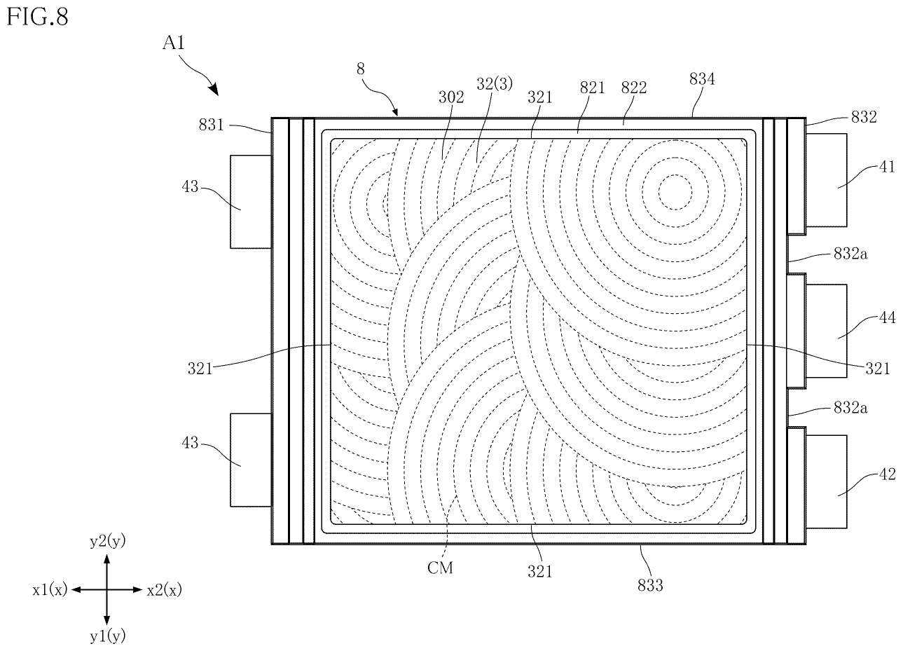

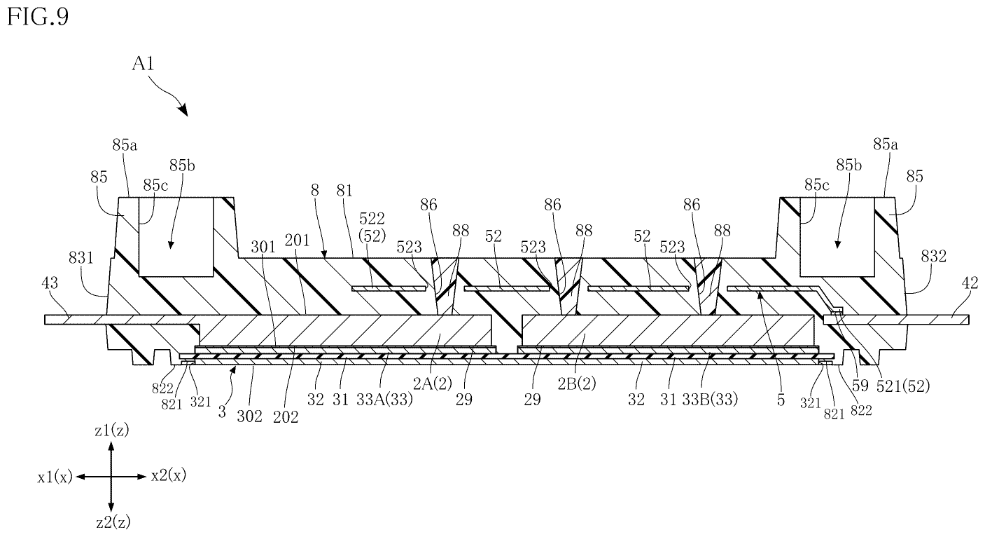

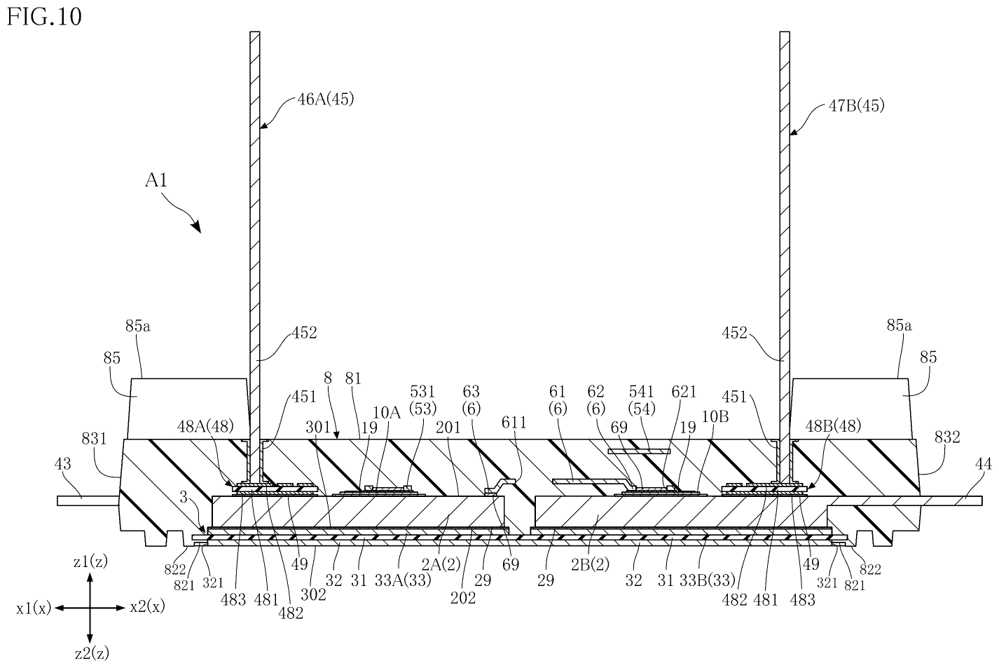

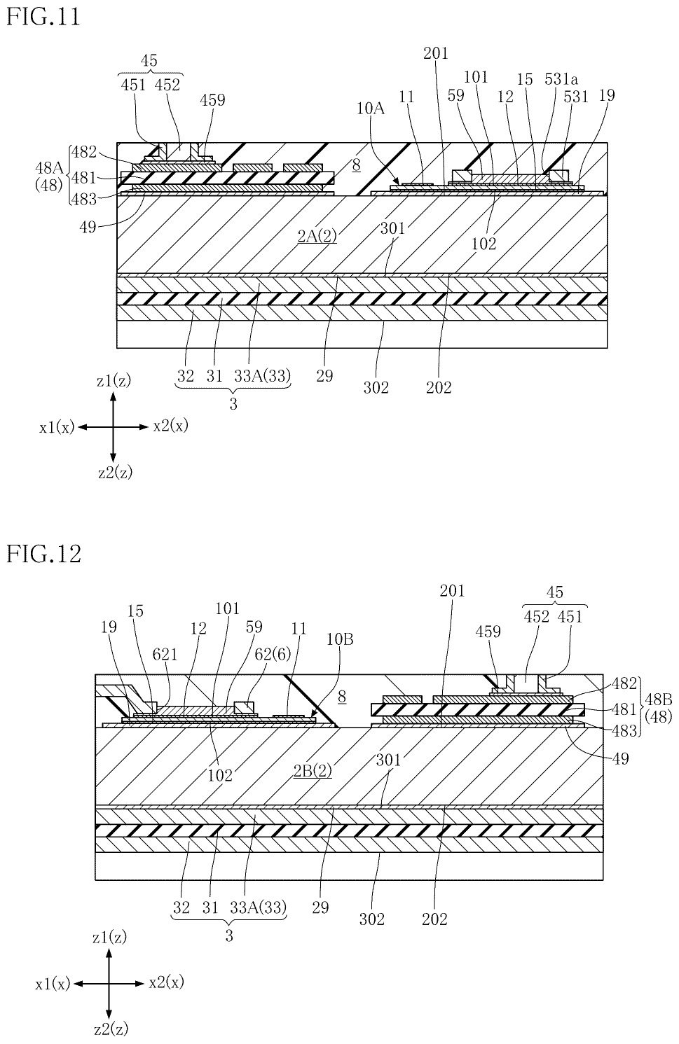

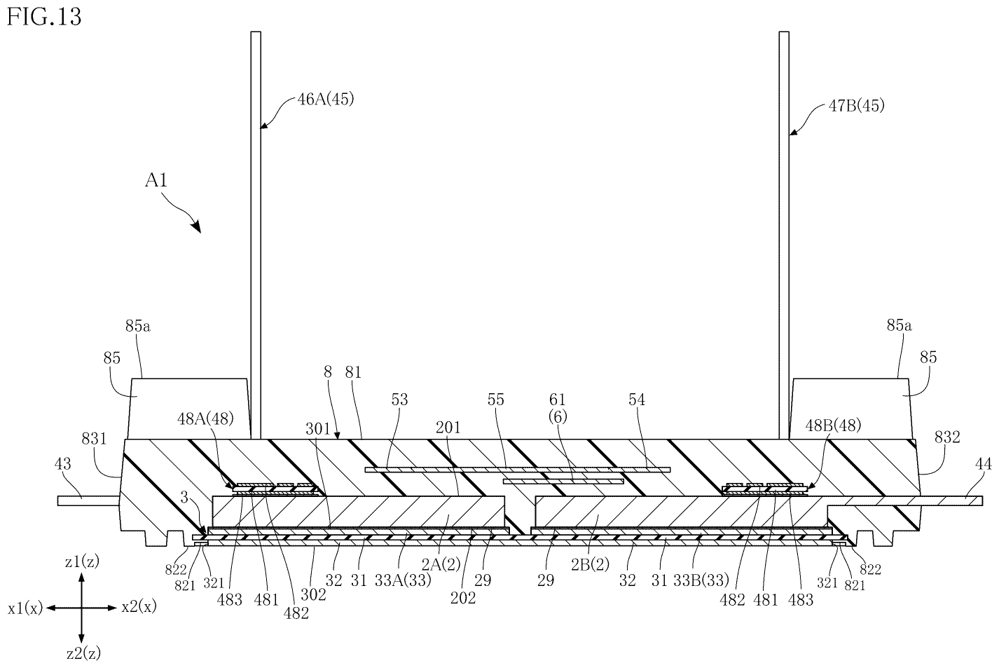

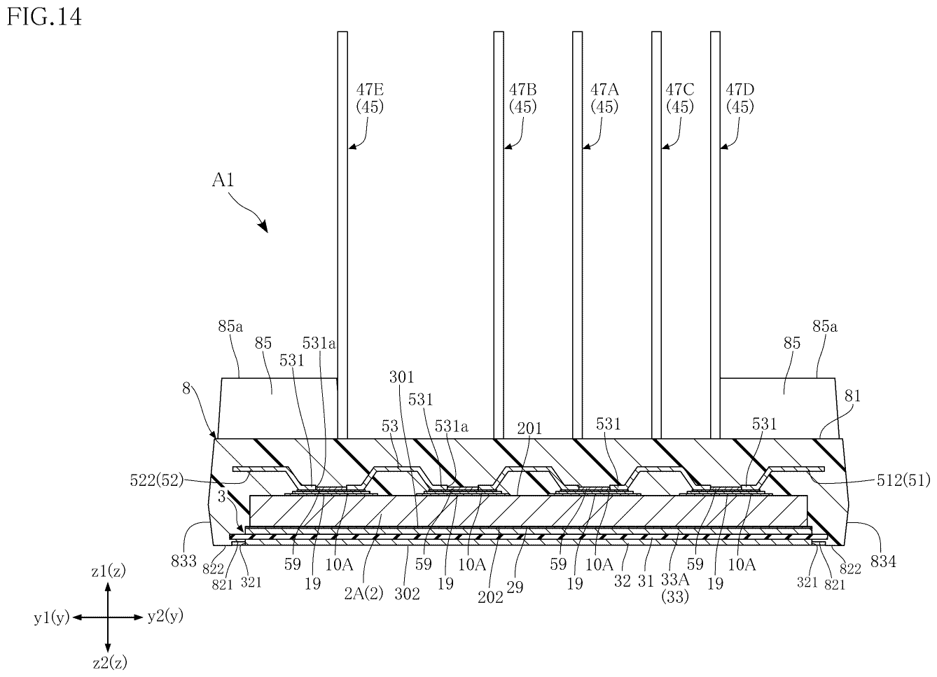

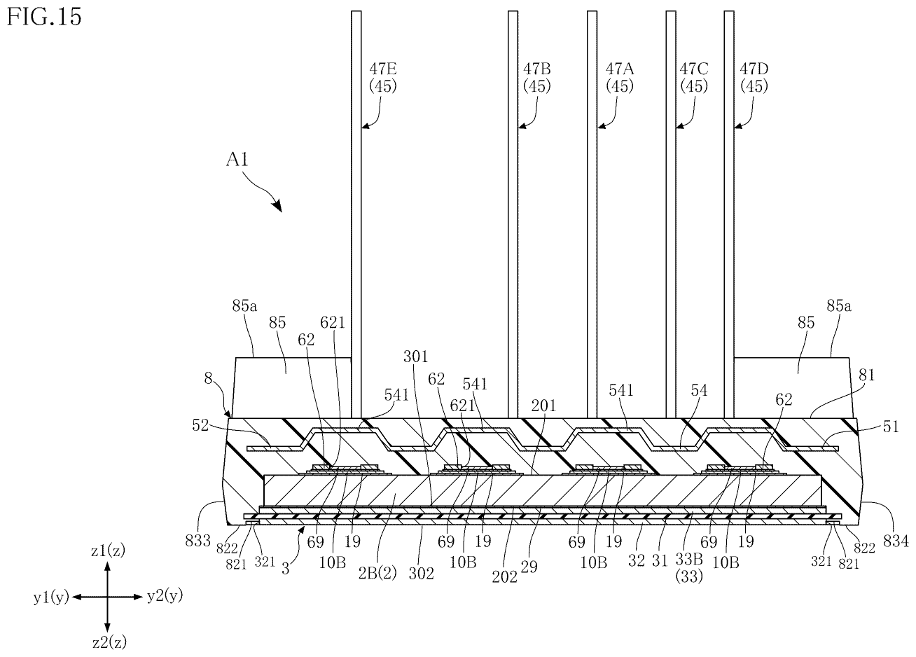

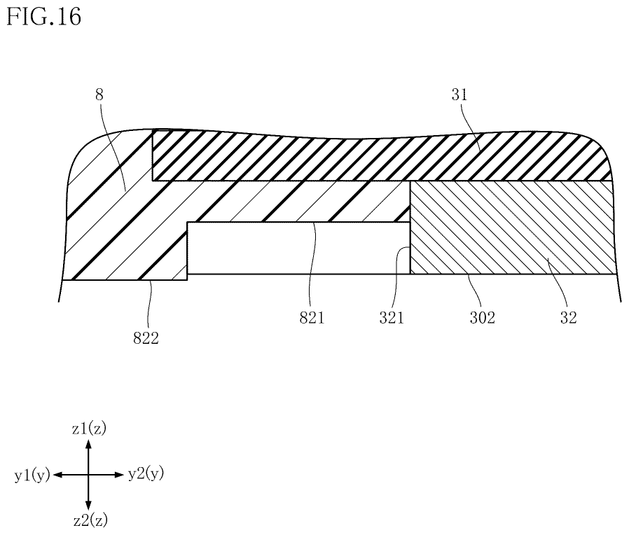

FIG. 1 is a perspective view of the semiconductor device A1. FIG. 2 is a perspective view corresponding to FIG. 1, with the sealing resin 8 omitted. FIG. 3 is a perspective view corresponding to FIG. 2, with the first conductive member 5 omitted. FIG. 4 is a plan view of the semiconductor device A1. FIG. 5 is a perspective view corresponding to FIG. 4, with the sealing resin 8 indicated by imaginary lines. FIG. 6 is a partial enlarged view in which a portion of FIG. 5 is enlarged, with the sealing resin 8 omitted. FIG. 7 is a plan view corresponding to FIG. 5, with the sealing resin 8 and the first conductive member 5 omitted and the second conductive member 6 indicated by imaginary lines. FIG. 8 is a bottom view of the semiconductor device A1. FIG. 9 is a sectional view taken along line IX-IX in FIG. 5. FIG. 10 is a sectional view taken along line X-X in FIG. 5. FIGS. 11 and 12 are partial enlarged views in which a portion of FIG. 10 is enlarged. FIG. 13 is a sectional view taken along line XIII-XIII in FIG. 5. FIG. 14 is a sectional view taken along line XIV-XIV in FIG. 5. FIG. 15 is a sectional view taken along line XV-XV in FIG. 5. FIG. 16 is a partial enlarged view in which a portion of FIG. 14 is enlarged.

In these figures, three mutually orthogonal directions are referred to as appropriate. The direction z is an example of the “thickness direction”, and hereinafter referred to as the “thickness direction z”. One direction orthogonal to the thickness direction z is the direction x, and hereinafter referred to as the “first direction x”. The direction y, which is orthogonal to both the thickness direction z and the first direction x, is hereinafter referred to as the “second direction y”. In the following description, “plan view” refers to a view as viewed in the thickness direction z.

The first semiconductor elements 10A and the second semiconductor elements 10B are electronic components that form the functional core of the semiconductor device A1. The constituent material of the first semiconductor elements 10A and the second semiconductor elements 10B is a semiconductor material mainly composed of, for example, SiC (silicon carbide). The semiconductor material is not limited to SiC, but may be Si (silicon), GaN (gallium nitride), or C (diamond). The first semiconductor elements 10A and the second semiconductor elements 10B may be power semiconductor chips having a switching function, such as MOSFETs (Metal Oxide Semiconductor Field Effect Transistors). The first semiconductor elements 10A and the second semiconductor elements 10B are MOSFETs in the present embodiment, but are not limited to this, and may be other transistors, such as IGBTs (Insulated Gate Bipolar Transistors). The first semiconductor elements 10A and the second semiconductor elements 10B are all of the same type. The first semiconductor elements 10A and the second semiconductor elements 10B are, for example, n-channel MOSFETs, but may be p-channel MOSFETs.

As shown in FIGS. 11 and 12, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart from each other in the thickness direction z. The element obverse surface 101 faces the z1 side in the thickness direction z, and the element reverse surface 102 faces the z2 side in the thickness direction z.

In the present embodiment, the semiconductor device A1 includes four first semiconductor elements 10A and four second semiconductor elements 10B. However, the number of first semiconductor elements 10A and the number of second semiconductor elements 10B are not limited to this, and may be changed as appropriate in accordance with the performance required of the semiconductor device A1. In the example of FIG. 7, four each of the first semiconductor elements 10A and the second semiconductor elements10B are provided. The number of first semiconductor elements 10A and the number of second semiconductor elements 10B may be two, three, or five or greater. The number of first semiconductor elements 10A and the number of second semiconductor elements 10B may be the same or may be different. The number of first semiconductor elements 10A and the number of second semiconductor elements 10B are determined based on the current capacity of the semiconductor device A1.

The semiconductor device A1 may be configured as a half-bridge type switching circuit. In such a case, in the semiconductor device A1, the second semiconductor elements 10B form the upper arm circuit, and the first semiconductor elements 10A form the lower arm circuit. In the upper arm circuit, the second semiconductor elements 10B are connected in parallel with each other. In the lower arm circuit, the first semiconductor elements 10A are connected in parallel with each other. Each second semiconductor element 10B and a relevant one of the first semiconductor elements 10A are connected in series to form a bridge layer.

As shown in FIGS. 7 and 14, each of the first semiconductor elements 10A is mounted on the conductive substrate 2. In the example shown in FIG. 7, the first semiconductor elements 10A may be aligned in the second direction y and are spaced apart from each other. Each of the first semiconductor elements 10A is conductively bonded to the conductive substrate 2 (the first conductive portion 2A, described later) via a conductive bonding material 19. With the first semiconductor elements 10A bonded to the first conductive portion 2A, the element reverse surfaces 102 face the first conductive portion 2A.

As shown in FIGS. 7 and 15, each of the second semiconductor elements 10B is mounted on the conductive substrate 2. In the example shown in FIG. 7, the second semiconductor elements 10B may be aligned in the second direction y and are spaced apart from each other. Each of the second semiconductor elements 10B is conductively bonded to the conductive substrate 2 (the second conductive portion 2B, described later) via a conductive bonding material 19. With the second semiconductor elements 10B bonded to the second conductive portion 2B, the element reverse surfaces 102 face the second conductive portion 2B. As understood from FIG. 7, the first semiconductor elements 10A and the second semiconductor elements 10B overlap with each other as viewed in the first direction x, but may not overlap with each other.

Each of the first semiconductor elements 10A and the second semiconductor elements 10B has a first obverse-surface electrode 11, a second obverse-surface electrode 12, a third obverse-surface electrode 13, and a reverse-surface electrode 15. The configurations of the first obverse-surface electrode 11, the second obverse-surface electrode 12, the third obverse-surface electrode 13 and the reverse-surface electrode 15 described below are common to the first semiconductor elements 10A and the second semiconductor elements 10B. The first obverse-surface electrode 11, the second obverse-surface electrode 12, and the third obverse-surface electrode 13 are provided on the element obverse surface 101. The first obverse-surface electrode 11, the second obverse-surface electrode 12, and the third obverse-surface electrode 13 are insulated from each other by an insulating film, not shown. The reverse-surface electrode 15 is provided on the element reverse surface 102.

The first obverse-surface electrode 11 is, for example, a gate electrode, through which a drive signal (e.g., gate voltage) for driving the first semiconductor element 10A (the second semiconductor element 10B) is inputted. In each first semiconductor element 10A (each second semiconductor element 10B), the second obverse-surface electrode 12 is, for example, a source electrode, through which the source current flows. The third obverse-surface electrode 13 is, for example, a source sense electrode, through which the source current flows. The reverse-surface electrode 15 is, for example, a drain electrode, through which the drain current flows. The reverse-surface electrode 15 covers the entire (or almost entire) element reverse surface 102. The reverse-surface electrode 15 is formed by Ag (silver) plating, for example.

Each of the first semiconductor elements 10A (the second semiconductor elements 10B) switches between a conducting state and a non-conducting state in response to a drive signal (gate voltage) inputted to the first obverse-surface electrode 11 (the gate electrode). In the conducting state, a current flows from the reverse-surface electrode 15 (the drain electrode) to the second obverse-surface electrode 12 (the source electrode). In the non-conducting state, this current does not flow. That is, each first semiconductor element 10A (each second semiconductor element 10B) performs a switching operation. The semiconductor device A1 uses the switching function of the first semiconductor elements 10A and the second semiconductor elements 10B to convert the DC voltage inputted between the single fourth terminal 44 and the two, i.e., the first and the second terminals 41 and 42 into e.g. AC voltage and outputs the AC voltage from the third terminal 43.

As shown in FIGS. 5 and 7, the semiconductor device A1 includes thermistors 17. The thermistors 17 are used as temperature detection sensors.

The conductive substrate 2 supports the first semiconductor elements 10A and the second semiconductor elements 10B. The conductive substrate 2 is bonded on the support substrate 3 via a conductive bonding material 29. The conductive substrate 2 is, for example, rectangular in plan view. The conductive substrate 2, together with the first conductive member 5 and the second conductive member 6, forms a path for the main circuit current switched by the first semiconductor elements 10A and the second semiconductor elements 10B.

The conductive substrate 2 includes a first conductive portion 2A and a second conductive portion 2B. Each of the first conductive portion 2A and the second conductive portion 2B is a plate made of a metal. The metal may be Cu (copper) or a copper alloy, for example. The first conductive portion 2A and the second conductive portion 2B, together with the first terminal 41, the second terminal 42, the third terminals 43 and the fourth terminal 44, form a conduction path to the first semiconductor elements 10A and the second semiconductor elements 10B. As shown in FIGS. 9 to 15, each of the first conductive portion 2A and the second conductive portion 2B is bonded on the support substrate 3 via a conductive bonding material 29. Each of the first semiconductor elements 10A is bonded to the first conductive portion 2A via a conductive bonding material 19. Each of the second semiconductor elements 10B is bonded to the second conductive portion 2B via a conductive bonding material 19. The constituent material of the conductive bonding materials 19 and the conductive bonding materials 29 is not particularly limited, and may be solder, metal paste or sintered metal, for example. As shown in FIGS. 3, 7, 9 and 10, the first conductive portion 2A and the second conductive portion 2B are spaced apart from each other in the first direction x. In the example shown in these figures, the first conductive portion 2A is located on the x1 side in the first direction x of the second conductive portion 2B. Each of the first conductive portion 2A and the second conductive portion 2B is, for example, rectangular in plan view. The first conductive portion 2A and the second conductive portion 2B overlap with each other as viewed in the first direction x. Each of the first conductive portion 2A and the second conductive portion 2B has dimensions of, for example, 15 mm to 25 mm in the first direction x, 30 mm to 40 mm in the second direction y, and 1.0 mm to 5.0 mm (preferably, about 2.0 mm) in the thickness direction z.

The conductive substrate 2 has an obverse surface 201 and a reverse surface 202. As shown in FIGS. 9, 10 and 13 to 15, the obverse surface 201 and the reverse surface 202 are spaced apart from each other in the thickness direction z. The obverse surface 201 faces the z1 side in the thickness direction z, and the reverse surface 202 faces the z2 side in the thickness direction z. The obverse surface 201 is constituted of the upper surface of the first conductive portion 2A and the upper surface of the second conductive portion 2B. The reverse surface 202 is constituted of the lower surface of the first conductive portion 2A and the lower surface of the second conductive portion 2B. The reverse surface 202 is bonded to the support substrate 3 to face the support substrate 3.

The support substrate 3 supports the conductive substrate 2. The support substrate 3 may be, for example, an AMB (Active Metal Brazing) substrate. The support substrate 3 includes an insulating layer 31, a first metal layer 32, and a second metal layer 33.

The insulating layer 31 is made of, for example, a ceramic material with excellent thermal conductivity. Examples of such a ceramic material include silicon nitride (SiN). The material of the insulating layer 31 is not limited to a ceramic material, and may be an insulating resin sheet, for example. The insulating layer 31 may be rectangular in plan view.

The second metal layer 33 is formed on the upper surface (the surface facing the z1 side in the thickness direction z) of the insulating layer 31. The constituent material of the second metal layer 33 includes Cu, for example. The constituent material may include A1 (aluminum) rather than Cu. The second metal layer 33 includes a first portion 33A and a second portion 33B. The first portion 33A and the second portion 33B are spaced apart from each other in the first direction x. The first portion 33A is located on the x1 side in the first direction x of the second portion 33B. The first conductive portion 2A is bonded to and supported by the first portion 33A. The second conductive portion 2B is bonded to and supported by the second portion 33B. Each of the first portion 33A and the second portion 33B is, for example, rectangular in plan view.

The first metal layer 32 is formed on the lower surface (the surface facing the z2 side in the thickness direction z) of the insulating layer 31. The constituent material of the first metal layer 32 is the same as the constituent material of the second metal layer 33. As shown in FIG. 8, the lower surface (the bottom surface 302, described later) of the first metal layer 32 is exposed from the sealing resin 8. The first metal layer 32 overlaps with both the first portion 33A and the second portion 33B in plan view.

As shown in FIGS. 9 to 15, the support substrate 3 has a support surface 301 and a bottom surface 302. The support surface 301 and the bottom surface 302 are spaced apart from each other in the thickness direction z. The support surface 301 faces the z1 side in the thickness direction z, and the bottom surface 302 faces the z2 side in the thickness direction z. As shown in FIG. 8, the bottom surface 302 is exposed from the sealing resin 8. Specifically, the second metal layer 33 has the support surface 301, and the first metal layer 32 has the bottom surface 302. The support surface 301 is the upper surface of the second metal layer 33 and constituted of the upper surface of the first portion 33A and the upper surface of the second portion 33B. The support surface 301 faces the conductive substrate 2, and the conductive substrate 2 is bonded to the support surface 301. The bottom surface 302 is the lower surface of the first metal layer 32. A heat dissipation member (e.g., a heat sink) or the like can be attached to the bottom surface 302. The dimension of the support substrate 3 in the thickness direction z (the distance from the support surface 301 to the bottom surface 302 in the thickness direction z) is, for example, 0.7 mm to 2.0 mm.

In the present embodiment, the bottom surface 302 has a grinding trace CM as shown in FIG. 8. The grinding trace CM is formed on the entire bottom surface 302. The grinding trace CM is the trace formed by grinding the bottom surface 302 with a grinding tool. The appearance (specific shape) of the grinding trace CM is not limited in any way. In the illustrated example, the grinding trace CM is regular patterns of lines made up of a plurality of circular lines. The bottom surface 302 is a flat surface with an improved flatness through grinding as described later. The amount of warpage of the bottom surface 302 is 100 μm or less (0 to 100 μm). The lower limit of the amount of warpage of the bottom surface 302 is not specifically defined, but may be 5 μm or more, for example.

As shown in FIGS. 8 to 10 and 13 to 15, the first metal layer 32 has side surfaces 321. In the present embodiment, the first metal layer 32 has four side surfaces 321. Each of the four side surfaces 321 is connected to the bottom surface 302. The four side surfaces 321 overlap with the periphery of the bottom surface 302 as viewed in the thickness direction z and are located on the z1 side in the thickness direction z relative to the bottom surface 302. Of the four side surfaces 321, two side surfaces 321 face in the first direction x and the other two side surfaces 321 face in the second direction y. Of the two side surfaces 321 facing in the first direction x, one faces the x1 side in the first direction x, and the other faces the x2 side in the first direction x. Of the two side surfaces 321 facing in the second direction y, one faces the y1 side in the second direction y, and the other faces the y2 side in the second direction y. In the present embodiment, at least some portions of the side surfaces 321 are exposed from the sealing resin 8. In the illustrated example, a portion of each side surface 321 is exposed from the sealing resin 8.

The first terminal 41, the second terminal 42, the third terminals 43, and the fourth terminal 44 are made of metal plates. The constituent material of the metal plates is, for example, Cu or a Cu alloy. In the example shown in FIGS. 1 to 5, 7 and 8, the semiconductor device A1 has one first terminal 41, one second terminal 42, one fourth terminal 44, and two third terminals 43.

The first terminal 41, the second terminal 42, and the fourth terminal 44 receive, as input, the DC voltage to be converted. The fourth terminal 44 is a positive electrode (P terminal), and the first terminal 41 and the second terminal 42 are negative electrodes (N terminals). The AC voltage converted by the first semiconductor elements 10A and the second semiconductor elements 10B is outputted from the third terminals 43. Each of the first terminal 41, the second terminal 42, the third terminals 43, and the fourth terminal 44 includes a portion covered with the sealing resin 8 and a portion exposed from the sealing resin 8.

As shown in FIG. 10, the fourth terminal 44 is formed integrally with the second conductive portion 2B. Unlike this configuration, the fourth terminal 44 may be provided separately from the second conductive portion 2B and conductively bonded to the second conductive portion 2B. As shown in FIG. 7, the fourth terminal 44 is located on the x2 side in the first direction x with respect to the second semiconductor elements 10B and the second conductive portion 2B (the conductive substrate 2). The fourth terminal 44 is electrically connected to the second conductive portion 2B and also electrically connected to the reverse-surface electrode 15 (the drain electrode) of each second semiconductor element 10B via the second conductive portion 2B.

As shown in FIG. 7, the first terminal 41 and the second terminal 42 are spaced apart from the second conductive portion 2B. As shown in FIGS. 5 and 6, the first conductive member 5 is bonded to the first terminal 41 and the second terminal 42. As shown in FIGS. 5 and 7, the first terminal 41 and the second terminal 42 are located on the x2 side in the first direction x with respect to the second semiconductor elements 10B and the second conductive portion 2B (the conductive substrate 2). The first terminal 41 and the second terminal 42 are electrically connected to the first conductive member 5 and also electrically connected to the second obverse-surface electrode 12 (the source electrode) of each first semiconductor element 10A via the first conductive member 5.

As shown in FIGS. 1 to 5 and 8, in the semiconductor device A1, the first terminal 41, the second terminal 42 and the fourth terminal 44 protrude from the sealing resin 8 to the x2 side in the first direction x. The first terminal 41, the second terminal 42, and the fourth terminal 44 are spaced apart from each other. The first terminal 41 and the second terminal 42 are located opposite to each other across the fourth terminal 44 in the second direction y. The first terminal 41 is located on the y2 side in the second direction y of the fourth terminal 44, and the second terminal 42 is located on the y1 side in the second direction y of the fourth terminal 44. The first terminal 41, the second terminal 42, and the fourth terminal 44 overlap with each other as viewed in the second direction y.

As understood from FIGS. 7 and 9, the two third terminals 43 are integrally formed with the first conductive portion 2A. Unlike this configuration, the third terminals 43 may be provided separately from the first conductive portion 2A and conductively bonded to the first conductive portion 2A. As shown in FIG. 7, the two third terminals 43 are located on the x1 side in the first direction x with respect to the first semiconductor elements 10A and the first conductive portion 2A (the conductive substrate 2). Each third terminal 43 is electrically connected to the first conductive portion 2A and also electrically connected to the reverse-surface electrode 15 (the drain electrode) of each first semiconductor element 10A via the first conductive portion 2A. The number of third terminals 43 is not limited to two, and may be one, or three or greater. When only one third terminal 43 is provided, the third terminal 43 is preferably connected to the middle part in the second direction y of the first conductive portion 2A.

Each of the control terminals 45 is a pin-shaped terminal for controlling the first semiconductor elements 10A and the second semiconductor elements 10B. The control terminals 45 include a plurality of first control terminals 46A to 46D and a plurality of second control terminals 47A to 47E. The first control terminals 46A to 46D are used to control the first semiconductor elements 10A, for example. The second control terminals 47A to 47E are used to control the second semiconductor elements 10B, for example.

The first control terminals 46A to 46D are spaced apart from each other in the second direction y. As shown in FIGS. 7 and 10, the first control terminals 46A to 46D are supported on the first conductive portion 2A via the control terminal support 48 (the first support portion 48A, described later). As shown in FIGS. 5 and 7, the first control terminals 46A to 46D are located between the first semiconductor elements 10A and the two third terminals 43 in the first direction X.

The first control terminal 46A is a terminal (a gate terminal) for inputting a drive signal for the first semiconductor elements 10A. The first control terminal 46A receives, as input, a drive signal for driving the first semiconductor elements 10A. (For example, a gate voltage is applied.)

The first control terminal 46B is a terminal (a source sense terminal) for detecting the source signal of the first semiconductor elements 10A. The voltage (the voltage corresponding to the source current) applied to the second obverse-surface electrode 12 (the source electrode) of each first semiconductor element 10A is detected at the first control terminal 46B.

The first control terminal 46C and the first control terminal 46D are electrically connected to a thermistor 17.

The second control terminals 47A to 47E are spaced apart from each other in the second direction y. As shown in FIGS. 7 and 10, the second control terminals 47A to 47E are supported on the second conductive portion 2B via the control terminal support 48 (the second support portion 48B, described later). As shown in FIGS. 5 and 7, the second control terminals 47A to 47E are located between the second semiconductor elements 10B and the first, the second and the fourth terminals 41, 42 and 44 in the first direction x.

The second control terminal 47A is a terminal (a gate terminal) for inputting a drive signal for the second semiconductor elements 10B. The second control terminal 47A receives, as input, a drive signal for driving the second semiconductor elements 10B. (For example, a gate voltage is applied.) The second control terminal 47B is a terminal (a source sense terminal) for detecting the source signal of the second semiconductor elements 10B. The voltage (the voltage corresponding to the source current) applied to the second obverse-surface electrode 12 (the source electrode) of each second semiconductor element 10B is detected at the second control terminal 47B. The second control terminal 47C and the second control terminal 47D are electrically connected to a thermistor 17. The second control terminal 47E is a terminal (a drain sense terminal) for detecting a drain signal of the second semiconductor elements 10B. The voltage (the voltage corresponding to the drain current) applied to the reverse-surface electrode 15 (the drain electrode) of each second semiconductor element 10B is detected at the second control terminal 47E.

Each of the control terminals 45 (the first control terminals 46A to 46D and the second control terminals 47A to 47E) includes a holder 451 and a metal pin 452.

The holders 451 are made of an electrically conductive material. As shown in FIGS. 11 and 12, the holders 451 are bonded to the control terminal support 48 (the first metal layer 482, described later) via a conductive bonding material 459. Each holder 451 includes a tubular portion, an upper flange portion, and a lower flange portion. The upper flange portion is connected to the upper part of the tubular portion, and the lower flange portion is connected to the lower part of the tubular portion. A metal pin 452 is inserted in at least the upper flange portion and the tubular portion of each holder 451. The holder 451 is mostly covered with the sealing resin 8. In the illustrated example, only the upper end surface of each holder 451 is exposed from the sealing resin 8.

The metal pins 452 are rod-like members extending in the thickness direction z. The metal pins 452 are supported by being press-fitted into the holders 451. The metal pins 452 are electrically connected to the control terminal support 48 (the first metal layer 482, described below) at least via the holders 451. When the lower ends (the ends on the z2 side in the thickness direction z) of the metal pins 452 are in contact with the conductive bonding material 459 within the through-holes of the holders 451 as in the example shown in FIGS. 11 and 12, the metal pins 452 are electrically connected to the control terminal support 48 via the conductive bonding material 459. The length in the thickness direction z of the metal pins 452 is not limited to the example shown in the figure, but can be selected as appropriate.

The control terminal support 48 supports the plurality of control terminals 45. The control terminal support 48 is interposed between the obverse surface 201 (the conductive substrate 2) and the control terminals 45 in the thickness direction z.

The control terminal support 48 includes a first support portion 48A and a second support portion 48B. The first support portion 48A is disposed on the first conductive portion 2A of the conductive substrate 2 and supports the first control terminals 46A to 46D of the control terminals 45. As shown in FIG. 11, the first support portion 48A is bonded to the first conductive portion 2A via a bonding material 49. The bonding material 49 may be electrically conductive or insulating, and solder may be used, for example. The second support portion 48B is disposed on the second conductive portion 2B of the conductive substrate 2 and supports the second control terminals 47A to 47E of the second control terminals 45. As shown in FIG. 12, the second support portion 48B is bonded to the second conductive portion 2B via a bonding material 49.

The control terminal support 48 (each of the first support portion 48A and the second support portion 48B) may be provided by, for example, a DBC substrate. The control terminal support 48 includes an insulating layer 481, a first metal layer 482, and a second metal layer 483 laminated on top of each other.

The insulating layer 481 is made of a ceramic material, for example. The insulating layer 481 may be rectangular in plan view.

As shown in FIGS. 11 and 12, the first metal layer 482 is formed on the upper surface of the insulating layer 481. Each control terminal 45 stands on the first metal layer 482. The first metal layer 482 is made of, for example, Cu or a Cu alloy. As shown in FIG. 7, the first metal layer 482 includes a first portion 482A, a second portion 482B, a third portion 482C, a fourth portion 482D, a fifth portion 482E, and a sixth portion 482F. The first portion 482A, the second portion 482B, the third portion 482C, the fourth portion 482D, the fifth portion 482E, and the sixth portion 482F are spaced apart and insulated from each other.

The first portion 482A, to which a plurality of wires 71 are bonded, is electrically connected to the first obverse-surface electrodes 11 (gate electrodes) of the first semiconductor elements 10A (the second semiconductor elements 10B) via the wires 71. The first portion 482A and the sixth portion 482F are connected to each other via a plurality of wires 73. Thus, the sixth portion 482F is electrically connected to the first obverse-surface electrodes 11 (gate electrodes) of the first semiconductor elements 10A (the second semiconductor elements 10B) via the wires 73 and the wires 71. As shown in FIG. 7, the first control terminal 46A is bonded to the sixth portion 482F of the first support portion 48A, and the second control terminal 47A is bonded to the sixth portion 482F of the second support portion 48B.

The second portion 482B, to which a plurality of wires 72 are bonded, is electrically connected to the second obverse-surface electrodes 12 (source electrodes) of the first semiconductor elements 10A (the second semiconductor elements 10B) via the wires 72. As shown in FIG. 7, the first control terminal 46B is bonded to the second portion 482B of the first support portion 48A, and the second control terminal 47B is bonded to the second portion 482B of the second support portion 48B.

A thermistor 17 is bonded to the third portion 482C and the fourth portion 482D. As shown in FIG. 7, the first control terminals 46C and 46D are bonded to the third portion 482C and the fourth portion 482D, respectively, of the first support portion 48A. The second control terminals 47C and 47D are bonded to the third portion 482C and the fourth portion 482D, respectively, of the second support portion 48B.

The fifth portion 482E of the first support portion 48A is not electrically connected to other components. The fifth portion 482E of the second support portion 48B, to which a wire 74 is bonded, is electrically connected to the second conductive portion 2B via the wire 74. As shown in FIG. 7, the second control terminal 47E is bonded to the fifth portion 482E of the second support portion 48B. Each of the wires 71 to 74 is, for example, a bonding wire. The constituent material of the wires 71 to 74 is not particularly limited, and may include Au (gold), A1, or Cu, for example.

As shown in FIGS. 11 and 12, the second metal layer 483 is formed on the lower surface of the insulating layer 481. As shown in FIG. 11, the second metal layer 483 of the first support portion 48A is bonded to the first conductive portion 2A via the bonding material 49. As shown in FIG. 12, the second metal layer 483 of the second support portion 48B is bonded to the second conductive portion 2B via the bonding material 49.

The first conductive member 5 and the second conductive member 6, together with the conductive substrate 2, form a path for the main circuit current switched by the first semiconductor elements 10A and the second semiconductor elements 10B. The first conductive member 5 and the second conductive member 6 are spaced apart from the obverse surface 201 (the conductive substrate 2) to the z1 side in the thickness direction z and overlap with the obverse surface 201 in plan view. In the present embodiment, each of the first conductive member 5 and the second conductive member 6 is provided by a plate made of a metal. The metal is, for example, Cu or a Cu alloy. Specifically, each of the first conductive member 5 and the second conductive member 6 is a metal plate bent as appropriate.

The first conductive member 5 is connected to the second obverse-surface electrode 12 (the source electrode) of each first semiconductor element 10A and the first and the second terminals 41 and 42 to electrically connect the second obverse-surface electrode 12 of each first semiconductor element 10A and the first and the second terminals 41 and 42 to each other. The first conductive member 5 forms a path for the main circuit current switched by the first semiconductor elements 10A. The first conductive member 5 has a maximum dimension in the first direction x of 25 mm to 40 mm, for example, and a maximum dimension in the second direction y of 30 mm to 45 mm, for example. As shown in FIGS. 6 and 7, the first conductive member 5 includes a first wiring portion 51, a second wiring portion 52, a third wiring portion 53, a fourth wiring portion 54, and a fifth wiring portion 55.

The first wiring portion 51 has a first end 511, a second end 512, and a plurality of openings 513. The first end 511 is connected to the first terminal 41. The first end 511 and the first terminal 41 are bonded together with a conductive bonding material 59. In plan view, the first wiring portion 51 as a whole has a band shape extending in the first direction x. In plan view, the first wiring portion 51 overlaps with both the second conductive portion 2B and the first conductive portion 2A.

The second end 512 is spaced apart from the first end 511 in the first direction x. As shown in FIG. 6, the second end 512 is located on the x1 side in the first direction x with respect to the first end 511.

In plan view, the openings 513 correspond to locations where the material is locally removed. The openings 513 are spaced apart from each other in the first direction x. In the illustrated example, the first wiring portion 51 has three openings 513. The opening 513 on the x2 side in the first direction x and the opening 513 in the middle in the first direction x are located at positions that overlap with the obverse surface 201 of the second conductive portion 2B (the conductive substrate 2) in plan view and do not overlap with the second semiconductor elements 10B in plan view. The opening 513 on the x1 side in the first direction x is located at a position that overlaps with the obverse surface 201 of the first conductive portion 2A (the conductive substrate 2) in plan view and does not overlap with the first semiconductor elements 10A in plan view. Each opening 513 is provided on the y2 side in the second direction y of the second conductive portion 2B (the first conductive portion 2A) in plan view. In the present embodiment, each opening 513 is an arcuate notch recessed from the y1-side edge to the y2 side in the second direction y in the first wiring portion 51. The shape in plan view of each opening 513 is not limited, and may be a notch as in the present embodiment, or a hole unlike the present embodiment.

The second wiring portion 52 has a third end 521, a fourth end 522, and a plurality of openings 523. The third end 521 is connected to the second terminal 42. The third end 521 and the second terminal 42 are bonded together with a conductive bonding material 59. In plan view, the second wiring portion 52 as a whole has a band shape extending in the first direction x. The second wiring portion 52 is spaced apart from the first wiring portion 51 in the second direction y. The second wiring portion 52 is located on the y1 side in the second direction y with respect to the first wiring portion 51. In plan view, the second wiring portion 52 overlaps with both the second conductive portion 2B and the first conductive portion 2A.

The fourth end 522 is spaced apart from the third end 521 in the first direction x. As shown in FIG. 6, the fourth end 522 is located on the x1 side in the first direction x with respect to the third end 521.

In plan view, the openings 523 correspond to locations where the material is locally removed. The openings 523 are spaced apart from each other in the first direction x. In the illustrated example, the second wiring portion 52 has three openings 523. The opening 523 on the x2 side in the first direction x and the opening 523 in the middle in the first direction x are located at positions that overlap with the obverse surface 201 of the second conductive portion 2B (the conductive substrate 2) in plan view and do not overlap with the second semiconductor elements 10B in plan view. The opening 523 on the x1 side in the first direction x is located at a position that overlaps with the obverse surface 201 of the first conductive portion 2A (the conductive substrate 2) in plan view and does not overlap with the first semiconductor elements 10A in plan view. Each opening 523 is provided on the y1 side in the second direction y of the second conductive portion 2B (the first conductive portion 2A) in plan view. In the present embodiment, each opening 523 is an arcuate notch recessed from the y2-side edge to the y1 side in the second direction y in the second wiring portion 52. The shape in plan view of each opening 523 is not limited, and may be a notch as in the present embodiment, or a hole unlike the present embodiment.

The third wiring portion 53 is connected to both the first wiring portion 51 (the second end 512) and the second wiring portion 52 (the fourth end 522). In plan view, the third wiring portion 53 as a whole has a band shape extending in the second direction y. As understood from FIG. 6, the third wiring portion 53 overlaps with the first semiconductor elements 10A in plan view. As shown in FIG. 14, the third wiring portion 53 is connected to each of the first semiconductor elements 10A.

The third wiring portion 53 has a plurality of dented regions 531. As shown in FIG. 14, each dented region 531 protrudes to the z2 side in the thickness direction z relative to other portions of the third wiring portion 53. The dented regions 531 are bonded to the first semiconductor elements 10A, respectively. Each dented region 531 of the third wiring portion 53 and the second obverse-surface electrode 12 of a relevant first semiconductor element 10A are bonded to each other via a conductive bonding material 59. The constituent material of the conductive bonding material 59 is not particularly limited, and may be solder, metal paste or sintered metal, for example. In the present embodiment, each dented region 531 is formed with an opening 531a. Preferably, each opening 531a is formed to overlap with the center portion of the relevant first semiconductor element 10A in plan view. The openings 531a may be through-holes formed in the dented regions 531 of the third wiring portion 53. The openings 531a may be used to position the first conductive member 5 relative to the conductive substrate 2. The shape in plan view of the openings 531a may be a perfect circle, or may be other shapes such as an ellipse or a rectangle.

The fourth wiring portion 54 is connected to both the first wiring portion 51 and the second wiring portion 52. In plan view, the fourth wiring portion 54 as a whole has a band shape extending in the second direction y. The fourth wiring portion 54 is connected to the first wiring portion 51 between the first end 511 and the second end 512, and connected to the second wiring portion 52 between the third end 521 and the fourth end 522. The fourth wiring portion 54 is spaced apart from the third wiring portion 53 in the first direction x. As shown in FIG. 6, the fourth wiring portion 54 is located on the x2 side in the first direction x with respect to the third wiring portion 53. The fourth wiring portion 54 overlaps with the second semiconductor elements 10B in plan view.

The fourth wiring portion 54 has a plurality of raised regions 541. As shown in FIG. 15, each raised region 541 protrudes to the z1side in the thickness direction z relative to other portions of the fourth wiring portion 54. As shown in FIGS. 6 and 15, the raised regions 541 and the second semiconductor elements 10B overlap with each other in plan view. In the present embodiment, as understood from FIG. 6, the dented regions 531 of the third wiring portion 53 and the raised regions 541 are located at the same positions in the second direction y.

The fifth wiring portion 55 is connected to both the third wiring portion 53 and the fourth wiring portion 54. In plan view, the fifth wiring portion 55 as a whole has a band shape extending in the first direction second direction x. In the present embodiment, the first conductive member 5 has a plurality of (three) fifth wiring portions 55. The plurality of fifth wiring portions 55 are located between the first wiring portion 51 and the second wiring portion 52 in the second direction y and spaced apart from each other in the second direction y. The fifth wiring portions 55 are disposed in parallel (or approximately parallel). The end on the x1 side in the first direction x of each fifth wiring portion 55 is connected to a part of the third wiring portion 53 between two adjacent dented regions 531 in the second direction y. The end on the x2 side in the first direction x of each fifth wiring portion 55 is connected to a part of the fourth wiring portion 54 between two adjacent raised regions 541 in the second direction y.

The second conductive member 6 is connected to the second obverse-surface electrode 12 (the source electrode) of each second semiconductor element 10B and the first conductive portion 2A to electrically connect the second obverse-surface electrode 12 of each second semiconductor element 10B and the first conductive portion 2A to each other. The second conductive member 6 forms a path for the main circuit current switched by the second semiconductor element 10B. As shown in FIGS. 6 and 7, the second conductive member 6 includes a main part 61, a plurality of first connecting ends 62, and a plurality of second connecting ends 63.

The main part 61 is located between the second semiconductor elements 10B and the first conductive portion 2A in the first direction x and has a band shape extending in the second direction y in plan view. As shown in FIG. 13, the main part 61 is located on the z2 side in the thickness direction z with respect to the fifth wiring portions 55 of the first conductive member 5 and located closer to the obverse surface 201 (the conductive substrate 2) than are the fifth wiring portions 55. The main part 61 overlaps with the fifth wiring portions 55 in plan view. In the present embodiment, as shown in FIGS. 6, 7, and 10, the main part 61 is formed with a plurality of openings 611. Each of the openings 611 may be a through-hole penetrating in the thickness direction z, for example. The openings 611 are aligned in the second direction y in a mutually spaced manner. The openings 611 do not overlap with the fifth wiring portion 55 in plan view. The openings 611 are formed to facilitate the flow of the resin material between the upper side (the z1 side in the thickness direction z) and the lower side (the z2 side in the thickness direction z) at or near the main part 61 (the second conductive member 6) when the flowable resin material is injected to form the sealing resin 8. The configuration of the main part 61 (the second conductive member 6) is not limited to this configuration. For example, the openings 611 may not be formed.

The first connecting ends 62 and the second connecting ends 63 are connected to the main part 61 and disposed correspondingly to the second semiconductor elements 10B. As shown in FIGS. 10 and 15, each of the first connecting ends 62 is bonded to the second obverse-surface electrode12 of a relevant one of the second semiconductor elements 10B via a conductive bonding material 69, and each of the second connecting ends 63 is bonded to the first conductive portion 2A via a conductive bonding material 69. The constituent material of the conductive bonding material 69 is not particularly limited and may include solder, a metal paste or sintered metal, for example. In the present embodiment, each of the first connecting ends 62 is formed with an opening 621. Preferably, each opening 621 is formed to overlap with the middle part of a relevant second semiconductor element 10B in plan view. The openings 621 may be through-holes penetrating in the thickness direction z, for example. The openings 621 may be used to position the second conductive member 6 relative to the conductive substrate 2. The shape in plan view of the openings 621 may be a perfect circle, or may be other shapes such as an ellipse or a rectangle.

The sealing resin 8 covers the first semiconductor elements 10A, the second semiconductor elements 10B, the conductive substrate 2, the support substrate 3 (excluding the bottom surface 302 and a part of each side surface 321), a part of each of the first terminal 41, the second terminal 42, the third terminals 43 and the fourth terminal 44, a part of each of the control terminals 45, the control terminal support 48, the first conductive member 5, the second conductive member 6, and the wires 71 to 74. The sealing resin 8 is made of, for example, a black epoxy resin. The sealing resin 8 may be formed by molding. The sealing resin 8 has dimensions of, for example, about 35 mm to 60 mm in the first direction x, about 35 mm to 50 mm in the second direction y, and about 4 mm to 15 mm in the thickness direction z. These dimensions are the size of the largest portion along each direction. In the present embodiment, the sealing resin 8 has a resin obverse surface 81, a first resin reverse surface 821, a second resin reverse surface 822, and a plurality of resin side surfaces 831 to 834.

As shown in FIGS. 9 and 14, the resin obverse surface 81 and the first and the second resin reverse surfaces 821, 822 are spaced apart from each other in the thickness direction z. The resin obverse surface 81 faces the z1 side in the thickness direction z. The control terminals 45 (the first control terminals 46A to 46D and the second control terminals 47A to 47E) protrude from the resin obverse surface 81. The first resin reverse surface 821 and the second resin reverse surface 822 face the z2 side in the thickness direction z. As shown in FIG. 8, the first resin reverse surface 821 surrounds the bottom surface 302 (the lower surface of the first metal layer 32) of the support substrate 3 as viewed in the thickness direction z. The bottom surface 302 of the support substrate 3 (the first metal layer 32) is exposed from the first resin reverse surface 821. As shown in FIGS. 9, 14 and 16, the first resin reverse surface 821 is located on the z1 side in the thickness direction z relative to the bottom surface 302 of the first metal layer 32 and recessed to the z1 side in the thickness direction z relative to the bottom surface 302. The inner edge of the first resin reverse surface 821 adjoins the side surfaces 321 of the first metal layer 32. The first resin reverse surface 821 has a surface roughness greater than that of other portions, such as the resin obverse surface 81, of the sealing resin 8. The second resin reverse surface 822 surrounds the first resin reverse surface 821 as viewed in the thickness direction z. As shown in FIGS. 9, 14, and 16, the second resin reverse surface 822 is located on the z2 side in the thickness direction z relative to the first resin reverse surface 821. Specifically, as shown in FIG. 16, the second resin reverse surface 822 is located on the z2 side in the thickness direction z relative to the bottom surface 302. The first resin reverse surface 821 having the above-described configuration may be formed by irradiating the region of the sealing resin 8 that surrounds the bottom surface 302 with a laser.

Each of the resin side surfaces 831 to 834 is connected to the resin obverse surface 81 and the second resin reverse surface 822 and located between these surfaces in the thickness direction z. As shown in FIG. 4, the resin side surface 831 and the resin side surface 832 are spaced apart from each other in the first direction x. The resin side surface 831 faces the x1 side in the first direction x, and the resin side surface 832 faces the x2 side in the first direction x. The two third terminals 43 protrude from the resin side surface 831, and the first terminal 41, the second terminal 42 and the fourth terminal 44 protrude from the resin side surface 832. As shown in FIG. 4, the resin side surface 833 and the resin side surface 834 are spaced apart from each other in the second direction y. The resin side surface 833 faces the y1 side in the second direction y, and the resin side surface 834 faces the y2 side in the second direction y.

As shown in FIG. 4, the resin side surface 832 is formed with a plurality of recesses 832a. Each of the recesses 832a is recessed in the first direction x in plan view. The recesses 832a include one formed between the first terminal 41 and the fourth terminal 44, and one formed between the second terminal 42 and the fourth terminal 44 in plan view. The recesses 832a are provided to increase the creepage distance along the resin side surface 832 between the first terminal 41 and the fourth terminal 44 and the creepage distance along the resin side surface 832 between the second terminal 42 and the fourth terminal 44.

As shown in FIGS. 9 and 10, the sealing resin 8 has a plurality of protrusions 85 and resin cavities 86.

The protrusions 85 protrude from the resin obverse surface 81 in the thickness direction z. The protrusions 85 are located near the four corners of the sealing resin 8 in plan view. Each of the protrusions 85 has a protrusion end surface 85a at its extremity (the end on the z1 side in the thickness direction z). The protrusion end surfaces 85a of the protrusions 85 are parallel (or generally parallel) with the resin obverse surface 81 and located in the same plane (x-y plane). Each of the protrusions 85 has the shape of, for example, a hollow truncated cone with a bottom. The protrusions 85 serve as spacers when the semiconductor device A1 is mounted on, for example, a control circuit board of a device that operates with the power generated by the semiconductor device A1. Each of the protrusions 85 has a recess 85b and an inner wall surface 85c defining the recess 85b. Each of the protrusions 85 may be columnar, which may be preferably a cylindrical column. The recess 85b has a cylindrical shape, preferably with the inner wall surface 85c defining a perfect circle in plan view.

The semiconductor device A1 may be mechanically fastened to the control circuit board or the like by screwing, for example. In such a case, each protrusion 85 may be formed with an internal thread on the inner wall surface 85c of the recess 85b. An insert nut may be inserted into the recess 85b of the protrusion 85.

As shown in FIG. 9, each resin cavity 86 extends from the resin obverse surface 81 to the obverse surface 201 of the conductive substrate 2 in the thickness direction z. The resin cavity 86 is tapered, with its sectional area decreasing as proceeding to the z2 side in the thickness direction z from the resin obverse surface 81 to the obverse surface 201. The resin cavities 86 are the portions where the sealing resin 8 is not formed during the molding of the sealing resin 8.

Though illustration is omitted, the resin cavities 86 are formed, for example, because the flowable resin material could not flow into these areas as a result of these areas being occupied by pressing members during the molding process of the sealing resin 8. Such pressing members are used to apply pressing force to the obverse surface 201 of the conductive substrate 2 during the molding process and inserted into the openings 513 and the openings 523 of the first conductive member 5. In this way, the pressing members hold the conductive substrate 2 without interference with the first conductive member 5, and warpage of the support substrate 3, to which the conductive substrate 2 is bonded, is suppressed.

In the present embodiment, the semiconductor device A1 includes resin fill portions 88 as shown in FIG. 9. The resin fill portions 88 are loaded into the resin cavities 86 to fill the resin cavities 86. The resin fill portions 88 may be made of epoxy resin as with the sealing resin 8, but may be made of a material different from the sealing resin 8.

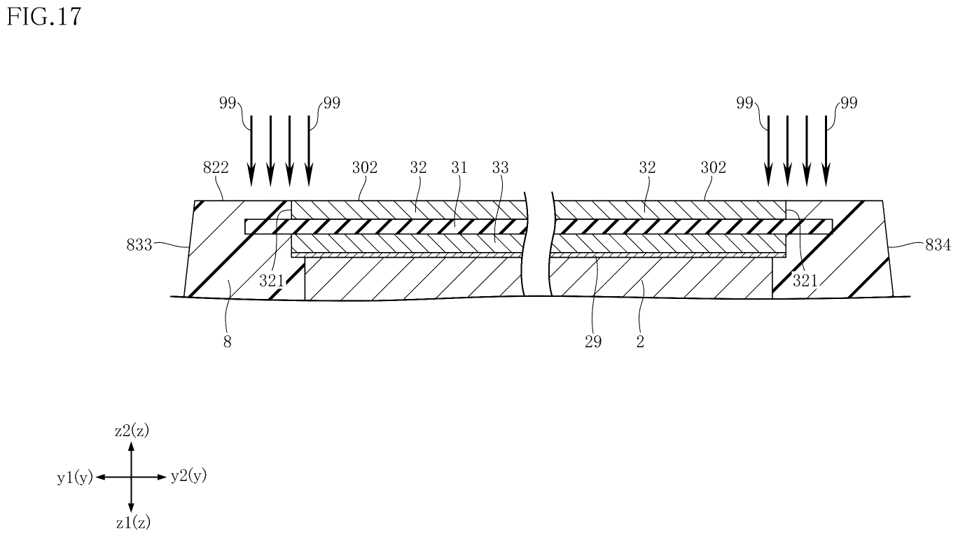

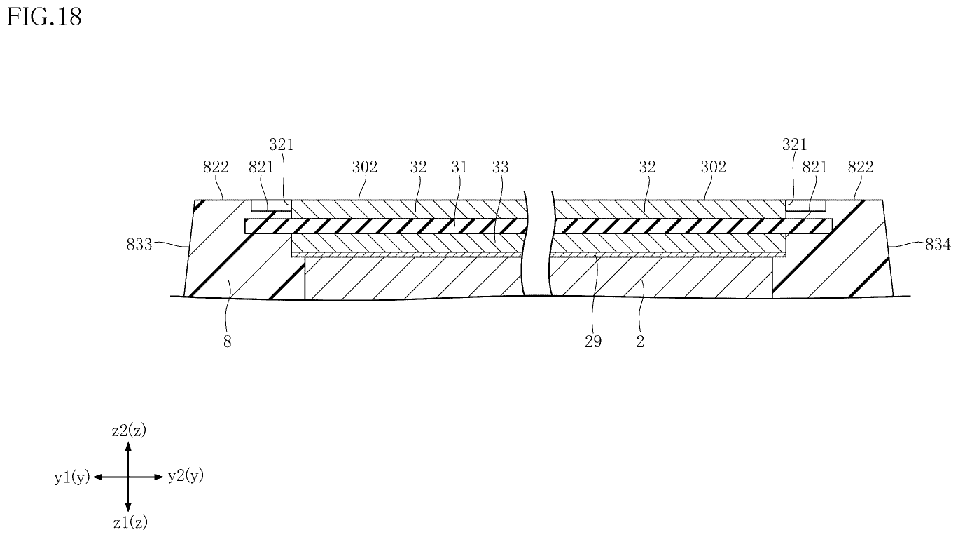

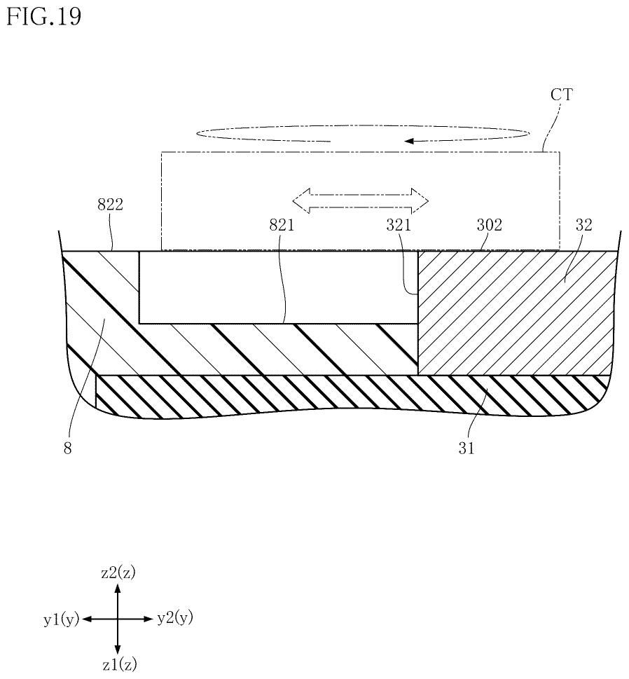

Next, an example of a method for manufacturing the semiconductor device A1 will be described with reference to FIGS. 17 to 19. FIGS. 17 to 19 are each a sectional view showing a step of the method for manufacturing the semiconductor device A1. FIGS. 17 and 18 each show a portion of the cross section shown in FIG. 14 as enlarged. FIG. 19 shows the same cross section as that shown in FIG. 16. In FIGS. 17 to 19, the process of forming the first resin reverse surface 821 on the sealing resin 8 and grinding the bottom surface 302 of the first metal layer 32 is shown.

FIG. 17 shows the state after the sealing resin 8 is formed by molding. In this state, the sealing resin 8 has the second resin reverse surface 822 facing the z2 side in the thickness direction z. The bottom surface 302 of the first metal layer 32 is exposed from the sealing resin 8 and flush (or generally flush) with the second resin reverse surface 822. In this state, a laser 99 is applied from the z2 side in the thickness direction z to the region of the second resin reverse surface 822 (sealing resin 8) that surrounds the bottom surface 302. The sealing resin 8 is partially removed at the region of the second resin reverse surface 822 that is irradiated with the laser 99. In the present embodiment, the laser 99 is applied also over the boundary between the second resin reverse surface 822 and the bottom surface 302 as viewed in the thickness direction z. Irradiation of the laser 99 is performed by controlling the intensity and irradiation time of the laser until the region of the sealing resin 8 irradiated with the laser 99 is recessed into a predetermined depth to the z1 side in the thickness direction z relative the bottom surface 302. As a result, the first resin reverse surface 821 is formed as shown in FIG. 18. The first resin reverse surface 821 surrounds the bottom surface 302 as viewed in the thickness direction z and is located on the z1 side in the thickness direction z relative to the bottom surface 302. By the irradiation of the laser 99 shown in FIG. 17, a portion of each side surface 321 of the first metal layer 32 is exposed from the sealing resin 8. The first resin reverse surface 821, which is formed by irradiation of the laser 99, has a surface roughness greater than that of other portions (the resin obverse surface 81 and the second resin reverse surface 822) of the sealing resin 8 formed by molding.

Next, the bottom surface 302 is ground as shown in FIG. 19. Grinding of the bottom surface 302 is performed with a grinding tool CT, such as a rotary griding wheel. Specifically, the grinding is performed by moving the grinding tool CT over the entire bottom surface 302 and the region surrounding the bottom surface 302 (the region overlapping with the first resin reverse surface 821 as viewed in the thickness direction z). As a result, the grinding trace CM as shown in FIG. 8 is formed. The grinding trace CM shown in FIG. 8 is an example when the grinding tool CT is a rotary grinding wheel or the like, and the specific pattern shape of the grinding trace CM is not limited. The griding wheel as the grinding tool CT or the abrasive grains or the like contained in the abrasive slurry has a hardness higher than that of the bottom surface 302 (the first metal layer 32). By grinding the bottom surface 302 using such a grinding tool CT, the flatness of the bottom surface 302 is improved. The amount of warpage of the bottom surface 302 after grinding is kept 100 μm or less.

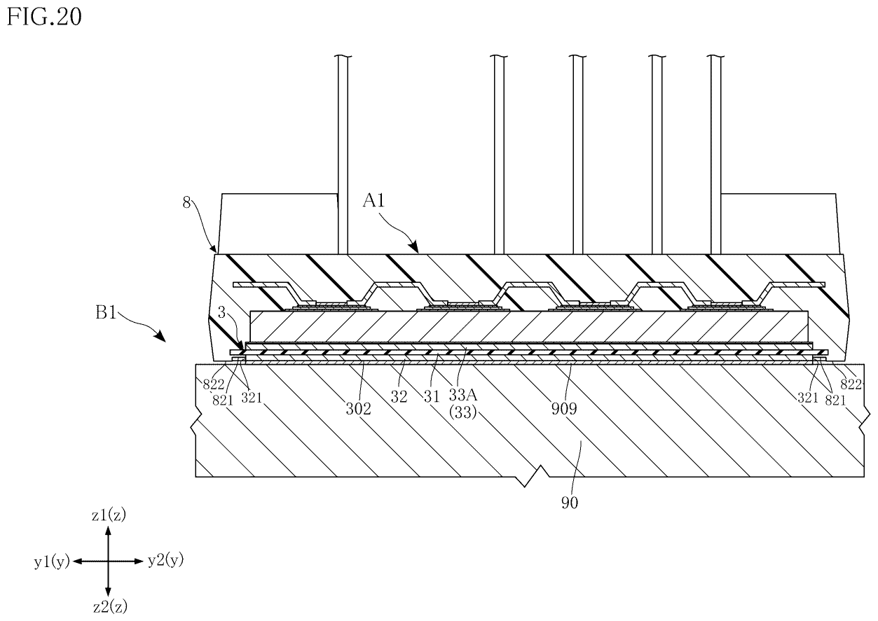

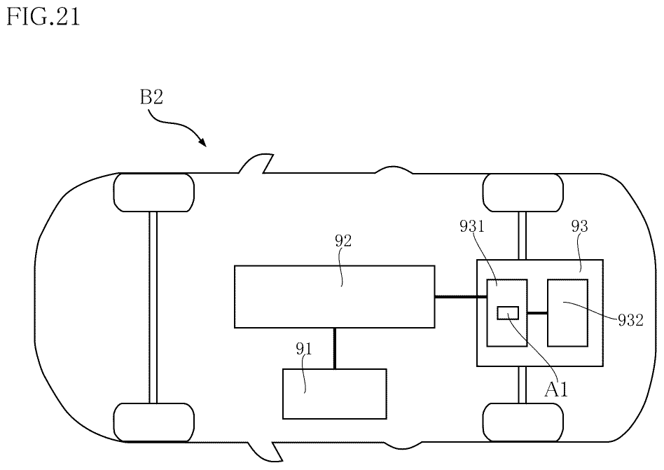

Next, an example of the use of the semiconductor device A1 will be described based on FIGS. 20 and 21.

FIG. 20 shows a semiconductor device assembly B1 that includes the semiconductor device A1. FIG. 20 is a schematic sectional view of the semiconductor device assembly B1. The semiconductor device assembly B1 includes the semiconductor device A1 and a heat sink 90.

As shown in FIG. 20, the heat sink 90 is disposed to face the bottom surface 302 of the semiconductor device A1 (the support substrate 3). The heat sink 90 is bonded to the bottom surface 302 via a bonding layer 909. The heat sink 90 is an example of the “heat dissipation member” of the present disclosure. The constituent material of the heat sink 90 is not particularly limited and may include, for example, A1 (aluminum), Cu (copper) or an alloy of these.

The bonding layer 909 bonds the upper surface (the surface facing the z1 side in the thickness direction z) of the heat sink 90 and the bottom surface 302 of the support substrate 3. The constituent material of the bonding layer 909 is not particularly limited and may include, for example, sintered metal. For example, the bonding layer 909 may be a sintered Ag (silver) layer. In this case, the thickness (the dimension in the thickness direction z) of the bonding layer 909 is relatively small and may be 50 to 500 μm, for example.

FIG. 21 is a schematic view of a vehicle B2 in which the semiconductor device A1 is mounted. The vehicle B2 may be, for example, an electric vehicle (EV).

As shown in FIG. 21, the vehicle B2 includes an on-board charger 91, a storage battery 92, and a drive system 93. The on-board charger 91 receives electric power wirelessly from a power supply facility (not shown) installed outdoors. Alternatively, power supply from the power supply facility to the on-board charger 91 may performed via a wired connection. The on-board charger 91 includes a step-up DC-DC converter. The voltage of the power supplied to the on-board charger 91 is increased by the converter and then supplied to the storage battery 92. The increased voltage is, for example, 600 V.

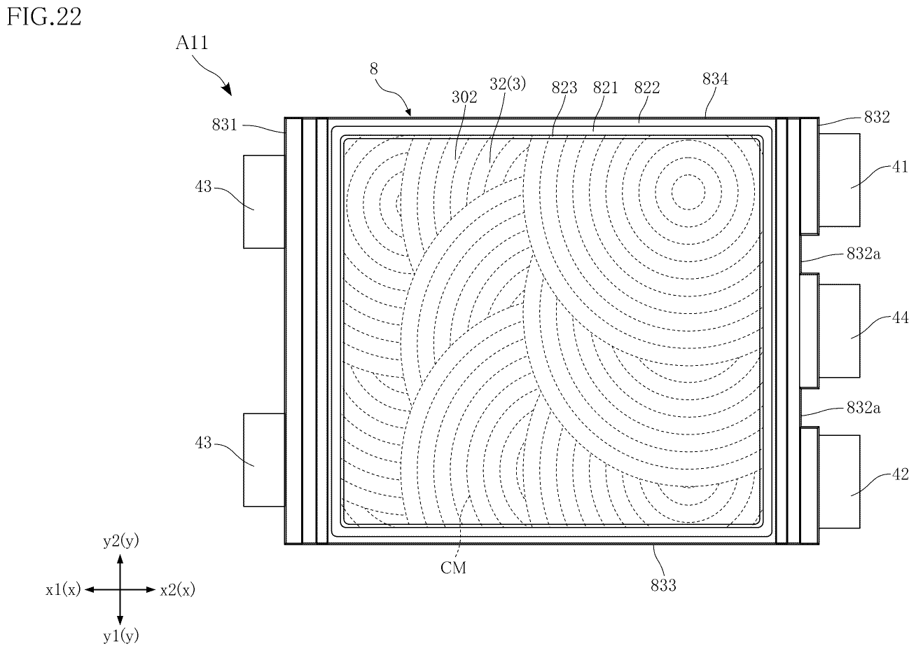

The drive system 93 drives the vehicle B2. The drive system 93 has an inverter 931 and a driving source 932. The semiconductor device A1 constitutes a part of the inverter 931. The power stored in the storage battery 92 is supplied to the inverter 931. The power supplied from the storage battery 92 to the inverter 931 is a direct current. Unlike the power system shown in FIG. 22, a step-up DC-DC converter may be additionally provided between the storage battery 92 and the inverter 931. The inverter 931 converts DC power into AC power. The inverter 931 including the semiconductor device A1 is electrically connected to the driving source 932. The driving source 932 has an AC motor and a transmission. When the AC power converted by the inverter 931 is supplied to the driving source 932, the AC motor rotates, and the rotation is transmitted to the transmission. The transmission appropriately reduces the rotation speed transmitted from the AC motor and rotates the drive shaft of the vehicle B2. Thus, the vehicle B2 is driven. When driving the vehicle B2, it is necessary to freely control the rotation speed of the AC motor based on the information such as the amount of movement of the accelerator pedal. The semiconductor device A1 in the inverter 931 is necessary to output the AC power with a frequency corresponding to the required rotation speed of the AC motor.

Next, the effects of the semiconductor device A1 will be described.

The semiconductor device A1 includes the support substrate 3, the first semiconductor elements 10A and the second semiconductor elements 10B (semiconductor elements), and the sealing resin 8. The support substrate 3 has the support surface 301 facing the z1 side in the thickness direction z and the bottom surface 302 facing the z2 side in the thickness direction z. The first semiconductor elements 10A and the second semiconductor elements 10B are disposed on the support surface 301. The bottom surface 302 is exposed from the sealing resin 8 and has the grinding trace CM. The bottom surface 302 has an improved flatness by grinding. This can improve the adhesion when a heat dissipation member such as the heat sink 90 is bonded to the bottom surface 302. Furthermore, the sealing resin 8 has the first resin reverse surface 821 facing the same side as the bottom surface 302 (the z2 side in the thickness direction z). The first resin reverse surface 821 surrounds the bottom surface 302 as viewed in the thickness direction z and is located on the z1 side in the thickness direction z relative to the bottom surface 302. The sealing resin 8 is recessed to the z1 side in the thickness direction z relative to the bottom surface 302 at the portion defining the first resin reverse surface 821 around the bottom surface 302. This reduces the amount of the sealing resin 8 that is ground away around the bottom surface 302 when grinding the bottom surface 302. Therefore, the grinding efficiency of the bottom surface 302 is improved, and wear of the grinding tool CT is suppressed, which leads to a longer life of the grinding tool CT.

The configuration in which the sealing resin 8 is recessed around the bottom surface 302 as described above makes it possible to appropriately press the heat sink 90 (the heat dissipation member) against the bottom surface 302 in bonding the heat sink 90 to the bottom surface 302 via the bonding layer 909. Therefore, a good bonding state between the bottom surface 302 (the support substrate 3, the semiconductor device A1) and the heat sink 90 via the bonding layer 909 is maintained.

The amount of warpage of the bottom surface 302 is 100 μm or less (0 to 100 μm). With such a configuration, the adhesion can be improved also in the case where the heat sink 90 is bonded to the bottom surface 302 via a relatively thin bonding layer 909, such as a layer of sintered metal. Therefore, a good bonding state between the bottom surface 302 and the heat sink 90 via the bonding layer 909 is maintained.

FIGS. 22 to 27 show variations of the present disclosure. In these figures, the elements that are identical or similar to those of the above embodiment are denoted by the same reference signs as those of the above embodiment, and the description thereof is omitted. Various parts of variations may be selectively used in any appropriate combination as long as it is technically compatible.

### First Variation

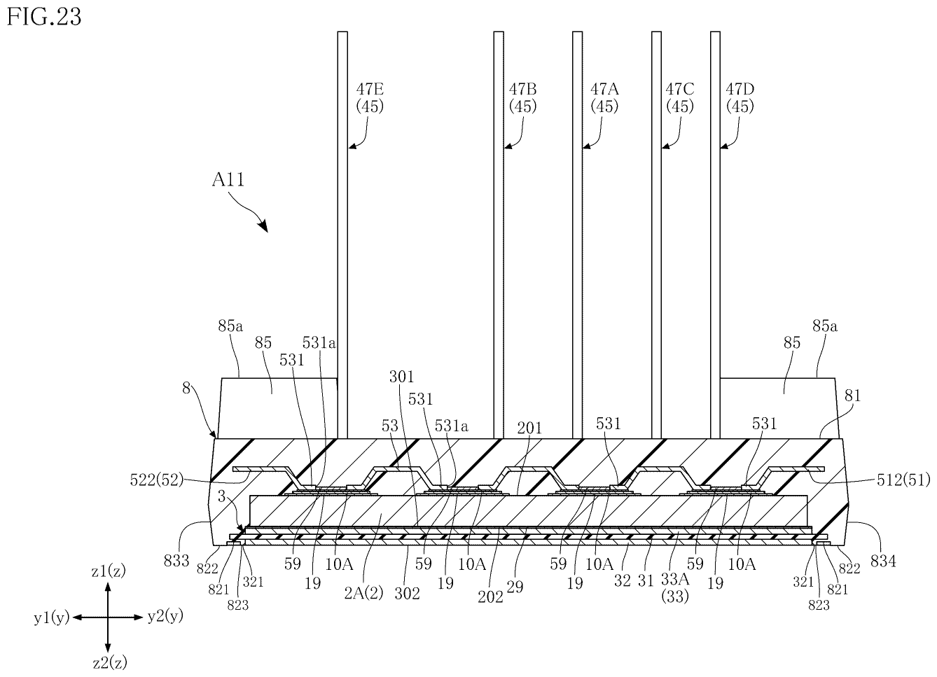

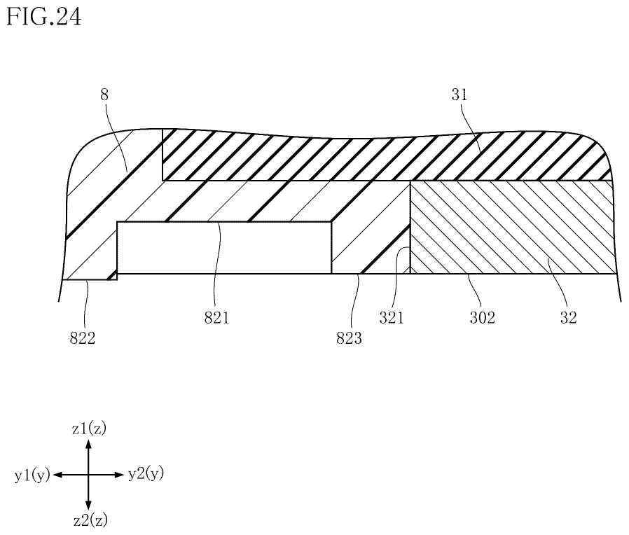

FIGS. 22 to 24 show a semiconductor device A11 according to a first variation of the first embodiment. FIG. 22 is a bottom view of the semiconductor device A11. FIG. 23 is a sectional view of the semiconductor device A11, showing the same cross section as that shown in FIG. 14. FIG. 24 is a partial enlarged view in which a portion of FIG. 23 is enlarged, showing the same cross section as that shown in FIG. 16.

The semiconductor device A11 differs from the semiconductor device A1 of the above embodiment in configuration of the sealing resin 8. In the semiconductor device A11, the sealing resin 8 further includes a third resin reverse surface 823. The third resin reverse surface 823 faces the z2 side in the thickness direction z. The third resin reverse surface 823 surrounds the bottom surface 302 as viewed in the thickness direction z. The third resin reverse surface 823 is flush with the bottom surface 302 and connected to the outer edge of the bottom surface 302. The first resin reverse surface 821 surrounds the third resin reverse surface 823 as viewed in the thickness direction z. In the semiconductor device A11, each side surface 321 of the first metal layer 32 is covered with the sealing resin 8. The sealing resin 8 having the third resin reverse surface 823 and the first resin reverse surface 821 is formed by shifting the laser irradiation region outward in each of the first direction x and the second direction y as compared with the semiconductor device A1 in the step of irradiating the region of the sealing resin 8 that surrounds the bottom surface 302 with a laser from the z2 side in the thickness direction z during the manufacture of the semiconductor device A11. In the semiconductor device A11, the grinding trace CM is formed on both the bottom surface 302 and the third resin reverse surface 823 connected to the bottom surface.

In the semiconductor device A11, the bottom surface 302 is exposed from the sealing resin 8 and has the grinding trace CM. The bottom surface 302 has an improved flatness by grinding. This can improve the adhesion when bonding a heat dissipation member such as the heat sink 90 to the bottom surface 302. Furthermore, the sealing resin 8 has the first resin reverse surface 821 facing the same side as the bottom surface 302 (the z2 side in the thickness direction z). The first resin reverse surface 821 surrounds the bottom surface 302 as viewed in the thickness direction z and is located on the z1 side in the thickness direction z relative to the bottom surface 302. The sealing resin 8 is recessed to the z1 side in the thickness direction z relative to the bottom surface 302 at the portion defining the first resin reverse surface 821 around the bottom surface 302. This reduces the amount of the sealing resin 8 that is ground away around the bottom surface 302 when grinding the bottom surface 302. Therefore, the grinding efficiency of the bottom surface 302 is improved, and wear of the grinding tool CT is suppressed, which leads to a longer life of the grinding tool CT.

The configuration in which the sealing resin 8 is recessed around the bottom surface 302 makes it possible to appropriately press a heat dissipation member against the bottom surface 302 in bonding the heat dissipation member to the bottom surface 302 via a bonding layer. Therefore, a good bonding state between the bottom surface 302 (the support substrate 3, the semiconductor device A11) and the heat dissipation member via a bonding layer is maintained.

The amount of warpage of the bottom surface 302 is 100 μm or less (0 to 100 μm). With such a configuration, the adhesion can be improved also in the case where the heat dissipation member is bonded to the bottom surface 302 via a relatively thin bonding layer, such as a layer of sintered metal. Therefore, a good bonding state between the bottom surface 302 and the heat dissipation member via a bonding layer is maintained.

### Second Variation

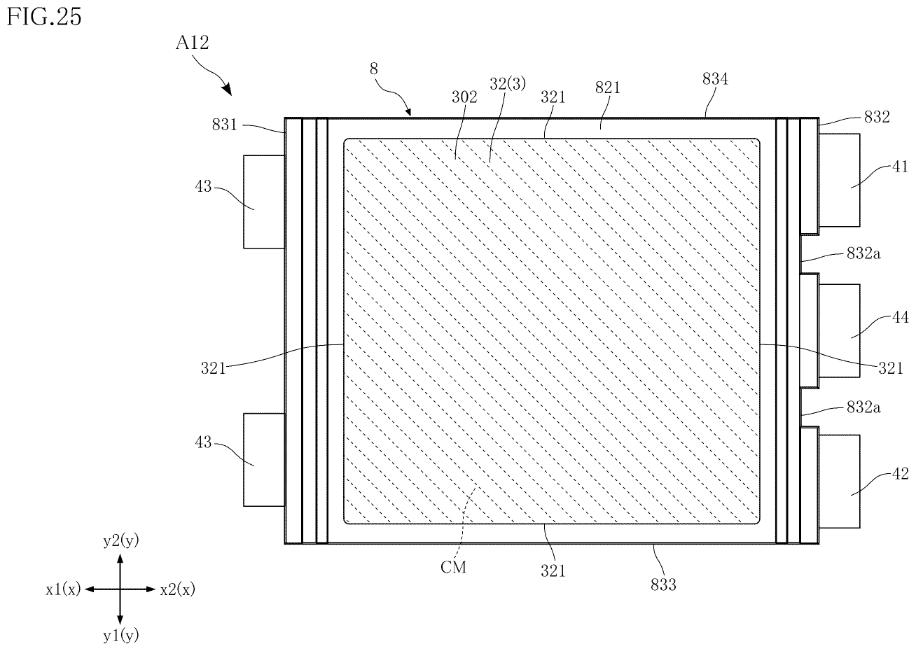

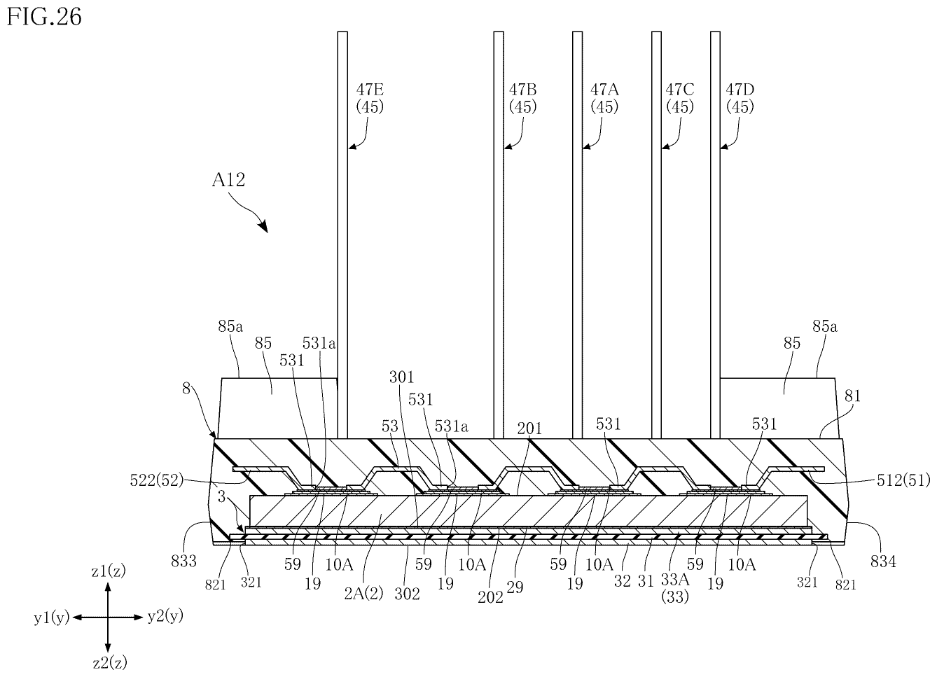

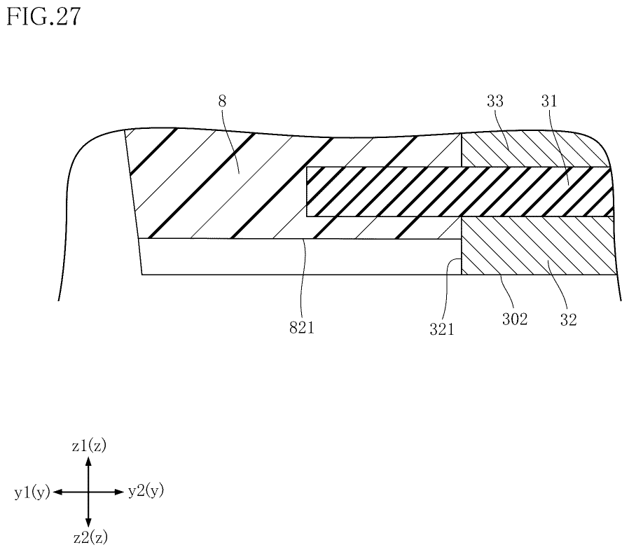

FIGS. 25 to 27 show a semiconductor device A12 according to a second variation of the first embodiment. FIG. 25 is a bottom view of the semiconductor device A12. FIG. 26 is a sectional view of the semiconductor device A12, showing the same cross section as that shown in FIG. 14. FIG. 27 is a partial enlarged view in which a portion of FIG. 26 is enlarged.

The semiconductor device A12 differs from the semiconductor device A1 of the above embodiment in configuration of the sealing resin 8. In the semiconductor device A12, the sealing resin 8 does not have the second resin reverse surface 822. In the semiconductor device A12, the first resin reverse surface 821 is formed also in the region where the second resin reverse surface 822 is formed in the semiconductor device A1 as viewed in the thickness direction z. The sealing resin 8 of the present variation is formed by expanding the laser irradiation region outward in each of the first direction x and the second direction y as compared with the semiconductor device A1 in the step of irradiating the region of the sealing resin 8 that surrounds the bottom surface 302 with a laser from the z2 side in the thickness direction z during the manufacture of the semiconductor device A12. In the semiconductor device A12 of the present variation, the grinding trace CM formed on the bottom surface 302 is made up of a plurality of parallel straight lines as shown in FIG. 25. Such a grinding trace CM may be formed, for example, when the grinding tool CT (see FIG. 19) described above is moved back and forth in a straight line.

In the semiconductor device A12, the bottom surface 302 is exposed from the sealing resin 8 and has the grinding trace CM. The bottom surface 302 has an improved flatness by grinding. This can improve the adhesion when bonding a heat dissipation member such as a heat sink to the bottom surface 302. Furthermore, the sealing resin 8 has the first resin reverse surface 821 facing the same side as the bottom surface 302 (the z2 side in the thickness direction z). The first resin reverse surface 821 surrounds the bottom surface 302 as viewed in the thickness direction z and is located on the z1 side in the thickness direction z relative to the bottom surface 302. The sealing resin 8 is recessed to the z1 side in the thickness direction z relative to the bottom surface 302 at the portion defining the first resin reverse surface 821 around the bottom surface 302. This reduces the amount of the sealing resin 8 that is ground away around the bottom surface 302 when grinding the bottom surface 302. Therefore, the grinding efficiency of the bottom surface 302 is improved, and wear of the grinding tool CT is suppressed, which leads to a longer life of the grinding tool CT.

The configuration in which the sealing resin 8 is recessed around the bottom surface 302 makes it possible to appropriately press a heat dissipation member against the bottom surface 302 in bonding the heat dissipation member to the bottom surface 302 via a bonding layer. Therefore, a good bonding state between the bottom surface 302 (the support substrate 3, the semiconductor device A12) and the heat dissipation member via a bonding layer is maintained.

The amount of warpage of the bottom surface 302 is 100 μm or less (0 to 100 μm). With such a configuration, the adhesion can be improved also in the case where the heat dissipation member is bonded to the bottom surface 302 via a relatively thin bonding layer, such as a layer of sintered metal. Therefore, a good bonding state between the bottom surface 302 and the heat dissipation member via a bonding layer is maintained.

The semiconductor device according to the present disclosure is not limited to the above-described embodiments. Various modifications in design may be made freely in the specific structure of each part of the semiconductor device according to the present disclosure.

The present disclosure includes the embodiments described in the following clauses.

### Clause 1

A semiconductor device comprising:
a support substrate including a support surface facing a first side in a thickness direction and a bottom surface facing a second side in the thickness direction;
at least one semiconductor element disposed on the support surface; and
a sealing resin covering the at least one semiconductor element and a portion of the support substrate, wherein
the bottom surface is exposed from the sealing resin and includes a grinding trace,
the sealing resin includes a resin obverse surface facing the first side in the thickness direction and a first resin reverse surface facing the second side in the thickness direction, and
the first resin reverse surface surrounds the bottom surface as viewed in the thickness direction and is located on the first side in the thickness direction relative to the bottom surface.

### Clause 2

The semiconductor device according to clause 1, wherein the first resin reverse surface has a surface roughness greater than that of the resin obverse surface.

### Clause 3

The semiconductor device according to clause 1 or 2, wherein the support substrate includes a first metal layer that includes the bottom surface.

### Clause 4

The semiconductor device according to clause 3, wherein the grinding trace is a regular pattern of lines.

### Clause 5

The semiconductor device according to clause 3 or 4, wherein the first metal layer includes a side surface connected to the bottom surface, and
the side surface overlaps with a periphery of the bottom surface as viewed in the thickness direction and is located on the first side in the thickness direction relative to the bottom surface.

### Clause 6

The semiconductor device according to clause 5, wherein at least a portion of the side surface is exposed from the sealing resin.

### Clause 7

The semiconductor device according to clause 5, wherein the side surface is covered with the sealing resin.

### Clause 8

The semiconductor device according to any one of clauses 3 to 7, wherein the support substrate includes an insulating layer, the first metal layer formed on the second side in the thickness direction of the insulating layer, and a second metal layer formed on the first side in the thickness direction of the insulating layer and including the support surface.

### Clause 9

The semiconductor device according to any one of clauses 3 to 8, wherein a constituent material of the first metal layer includes copper.

### Clause 10

The semiconductor device according to any one of clauses 1 to 9, wherein a constituent material of the sealing resin includes an epoxy resin.

### Clause 11

The semiconductor device according to any one of clauses 1 to 10, wherein the sealing resin includes a second resin reverse surface facing the second side in the thickness direction, and the second resin reverse surface surrounds the first resin reverse surface as viewed in the thickness direction and is located on the second side in the thickness direction relative to the first resin reverse surface.

### Clause 12

The semiconductor device according to clause 11, wherein the second resin reverse surface is located on the second side in the thickness direction relative to the bottom surface.

### Clause 13

The semiconductor device according to any one of clauses 1 to 12, wherein the bottom surface has an amount of warpage of 100 μm or less.

### Clause 14

A semiconductor device assembly comprising:
the semiconductor device as set forth in any one of clauses 1 to 13; and
a heat dissipation member bonded to the bottom surface.

### Clause 15.

A vehicle comprising:
a driving source; and
the semiconductor device as set forth in any one of clauses 1 to 13,
wherein the semiconductor device is electrically connected to the driving source.

### Clause 16

A method for manufacturing a semiconductor device that comprises:
a support substrate including a support surface facing a first side in a thickness direction and a bottom surface facing a second side in the thickness direction;
at least one semiconductor element disposed on the support surface, and
a sealing resin covering the at least one semiconductor element and a portion of the support substrate,
the method comprising the steps of:
forming a first resin reverse surface located on the first side in the thickness direction relative to the bottom surface by irradiating at least a region of the sealing resin that surrounds the bottom surface with a laser from the second side in the thickness direction; and
grinding the bottom surface with a grinding tool.

### REFERENCE NUMERALS

A1, A11, A12: Semiconductor device 10A: First semiconductor element
10B: Second semiconductor element 101: Element obverse surface
102: Element reverse surface 11: First obverse-surface electrode
102: Second obverse-surface electrode 13: Third obverse-surface electrode
15: Reverse-surface electrode 17: Thermistor
19: Conductive bonding material 2: Conductive substrate
2A: First conductive portion 2B: Second conductive portion
201: Obverse surface 202: Reverse surface
29: Conductive bonding material 3: Support substrate
301: Support surface 302: Bottom surface
31: Insulating layer 32: First metal layer
321: Side surface 33: Second metal layer
33A: First portion 33B: Second portion
41: First terminal 42: Second terminal
43: Third terminal 44: Fourth terminal
45: Control terminal 451: Holder
452: Metal pin 459: Conductive bonding material
46A, 46B, 46C, 46D: First control terminal
47A, 47B, 47C, 47D, 47E: Second control terminal
48: Control terminal support 481: Insulating layer
482: First metal layer 482A: First portion
482B: Second portion 482C: Third portion
482D: Fourth portion 482E: Fifth portion
482F: Sixth portion 483: Second metal layer
49: Bonding material 5: First conductive member
51: First wiring portion 511: First end
512: Second end 513: Opening
52: Second wiring portion 521: Third end
522: Fourth end 53: Third wiring portion
531: Dented region 531a: Opening
54: Fourth wiring portion 541: Raised region
55: Fifth wiring portion 59: Conductive bonding material
6: Second conductive member 61: Main part
611: Opening 62: First connecting end
621: Opening 63: Second connecting end
69: Conductive bonding material 71, 72, 73,74: Wire
8: Sealing resin 81: Resin obverse surface
821: First resin reverse surface 822: Second resin reverse surface
823: Third resin reverse surface 831, 832: Resin side surface
832a: Recess 833, 834: Resin side surface
85: Protrusion 85a: First protrusion end surface
85b: Recess 85c: Inner wall surface
86: Resin cavity 88: Resin fill portion
90: Heat sink (Heat dissipation member) 909: Bonding layer
91: On-board charger 91: Storage battery 93: Drive system 931: Inverter
932: Driving source 99: Laser CM: Grinding trace CT: Grinding tool
x: First direction y: Second direction z: Thickness direction

1. A semiconductor device comprising:
a support substrate including a support surface facing a first side in a thickness direction and a bottom surface facing a second side in the thickness direction;
at least one semiconductor element disposed on the support surface; and
a sealing resin covering the at least one semiconductor element and a portion of the support substrate, wherein
the bottom surface is exposed from the sealing resin and includes a grinding trace,
the sealing resin includes a resin obverse surface facing the first side in the thickness direction and a first resin reverse surface facing the second side in the thickness direction, and
the first resin reverse surface surrounds the bottom surface as viewed in the thickness direction and is located on the first side in the thickness direction relative to the bottom surface.

2. The semiconductor device according to claim 1, wherein the first resin reverse surface has a surface roughness greater than that of the resin obverse surface.

3. The semiconductor device according to claim 1, wherein the support substrate includes a first metal layer that includes the bottom surface.

4. The semiconductor device according to claim 3, wherein the grinding trace is a regular pattern of lines.

5. The semiconductor device according to claim 3, wherein the first metal layer includes a side surface connected to the bottom surface, and
the side surface overlaps with a periphery of the bottom surface as viewed in the thickness direction and is located on the first side in the thickness direction relative to the bottom surface.

6. The semiconductor device according to claim 5, wherein at least a portion of the side surface is exposed from the sealing resin.

7. The semiconductor device according to claim 5, wherein the side surface is covered with the sealing resin.

8. The semiconductor device according to claim 3, wherein the support substrate includes an insulating layer, the first metal layer formed on the second side in the thickness direction of the insulating layer, and a second metal layer formed on the first side in the thickness direction of the insulating layer and including the support surface.

9. The semiconductor device according to claim 3, wherein a constituent material of the first metal layer includes copper.

10. The semiconductor device according to claim 1, wherein a constituent material of the sealing resin includes an epoxy resin.

11. The semiconductor device according to claim 1, wherein the sealing resin includes a second resin reverse surface facing the second side in the thickness direction, and
the second resin reverse surface surrounds the first resin reverse surface as viewed in the thickness direction and is located on the second side in the thickness direction relative to the first resin reverse surface.

12. The semiconductor device according to claim 11, wherein the second resin reverse surface is located on the second side in the thickness direction relative to the bottom surface.

13. The semiconductor device according to claim 1, wherein the bottom surface has an amount of warpage of 100 μm or less.

14. A semiconductor device assembly comprising:
the semiconductor device as set forth in claim 1; and
a heat dissipation member bonded to the bottom surface.

15. A vehicle comprising:
a driving source; and
the semiconductor device as set forth in claim 1,
wherein the semiconductor device is electrically connected to the driving source.

16. A method for manufacturing a semiconductor device that comprises:
a support substrate including a support surface facing a first side in a thickness direction and a bottom surface facing a second side in the thickness direction;
at least one semiconductor element disposed on the support surface, and
a sealing resin covering the at least one semiconductor element and a portion of the support substrate,
the method comprising the steps of:
forming a first resin reverse surface located on the first side in the thickness direction relative to the bottom surface by irradiating at least a region of the sealing resin that surrounds the bottom surface with a laser from the second side in the thickness direction; and
grinding the bottom surface with a grinding tool.
